(19) United States
(12) Patent Application Publication
(10) Pub. No.: US 2025/0274098 A1
(43) Pub. Date: Aug. 28, 2025

(54) ACOUSTIC WAVE DEVICE AND FILTER DEVICE

(71) Applicant: Murata Manufacturing Co., Ltd., Nagaokakyo-shi (JP)

(72) Inventors: Kentaro NAKAMURA, Nagaokakyo-shi (JP); Takuya YABU, Nagaokakyo-shi (JP)

(21) Appl. No.: 19/207,606

(22) Filed: May 14, 2025

Related U.S. Application Data
(63) Continuation of application No. PCT/JP2023/040852, filed on Nov. 14, 2023.

(30) Foreign Application Priority Data
Nov. 28, 2022 (JP) 2022-189463

(51) Int. Cl. H03H 9/13; H03H 9/02; H03H 9/17; H03H 9/56

(52) U.S. Cl. CPC H03H 9/132; H03H 9/02086; H03H 9/02228; H03H 9/173; H03H 9/175; H03H 9/568

(57) ABSTRACT

An acoustic wave device includes an IDT electrode including first and second electrode fingers respectively connected to first and second busbars, and first and second electrode patterns. A region between first and second envelopes is an intersecting region. A tip portion of at least one of the first and second electrode fingers faces at least one of the first and second electrode patterns. In plan view, a shape of the first and second electrode fingers each include a curved portion in the intersecting region, and when a wavelength defined by an electrode finger pitch of the IDT electrode is A, a distance between the tip portion of the electrode fingers that faces the electrode pattern and the electrode pattern is about 0.5λ or less.

### CROSS REFERENCE TO RELATED APPLICATIONS

This application claims the benefit of priority to Japanese Patent Application No. 2022-189463 filed on Nov. 28, 2022 and is a Continuation Application of PCT Application No. PCT/JP2023/040852 filed on Nov. 14, 2023. The entire contents of each application are hereby incorporated herein by reference.

### BACKGROUND OF THE INVENTION

### 1. Field of the Invention

The present invention relates to acoustic wave devices and filter devices.

### 2. Description of the Related Art

In the related art, acoustic wave devices have been widely used in filters for cellular phones, or the like. International Publication No. 2011/108229 discloses an example of an acoustic wave device. In this acoustic wave device, an IDT (Interdigital Transducer) electrode is provided on a piezoelectric substrate. Shapes of a plurality of electrode fingers of the IDT include a curved shape. More specifically, each of the electrode fingers extends along a curved line from a center of a region where the IDT electrode intersects to a common electrode.

In an IDT electrode of an acoustic wave device described in International Publication No. 2011/108229, an electrode finger pitch at a central portion in a direction in which the plurality of electrode fingers extend is narrower than that of an electrode finger at an end portion in the direction. Therefore, an effect of suppressing responses from spurious waves can be obtained. However, leakage of acoustic wave energy cannot be reduced or prevented sufficiently, and a Q factor cannot be increased sufficiently.

### SUMMARY OF THE INVENTION

Example embodiments the present invention provide acoustic wave devices and a filter devices each with an increased Q factor.

An acoustic wave device according to an example embodiment of the present invention includes a piezoelectric substrate including a piezoelectric body layer, and an IDT electrode on the piezoelectric body layer and including a pair of busbars and a plurality of electrode fingers, the pair of busbars include a first busbar and a second busbar opposed to each other, the plurality of electrode fingers include a plurality of first electrode fingers and a plurality of second electrode fingers, one end of each of the plurality of first electrode fingers is connected to the first busbar, one end of each of the plurality of second electrode fingers is connected to the second busbar, and the plurality of first electrode fingers and the plurality of second electrode fingers are interdigitated with each other, an imaginary line connecting tip portions of the plurality of second electrode fingers is a first envelope, and an imaginary line connecting tip portions of the plurality of first electrode fingers is a second envelope, and a region between the first envelope and the second envelope in the IDT electrode is an intersecting region, the acoustic wave device further includes a plurality of electrode patterns on the piezoelectric body layer and between at least one of the first busbar and the intersecting region and between the second busbar and the intersecting region, of the plurality of electrode fingers, the tip portion of at least one of the plurality of first electrode fingers or the tip portion of at least one of the plurality of second electrode fingers faces at least one of the electrode patterns, and in plan view, a shape of the plurality of first electrode fingers and a shape of the plurality of second electrode fingers each include a curved portion in the intersecting region, and when a wavelength defined by an electrode finger pitch of the IDT electrode is A, a distance between the tip portion of the electrode finger among the plurality of electrode fingers that faces the electrode pattern and the electrode pattern is about 0.5λ or less.

A filter device according to an example embodiment of the present invention includes a plurality of acoustic wave resonators, and at least one of the acoustic wave resonators is defined by an acoustic wave resonator according to an example embodiment of the present invention.

According to each of the acoustic wave devices and the filter devices according to example embodiments of the present invention, a Q factor is improved.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic cross-sectional view along I-I line in FIG. 1.

FIG. 3 is a schematic plan view for describing a configuration of an IDT electrode in the first example embodiment of the present invention.

FIG. 4 is a schematic plan view of an acoustic wave device in the related art.

FIG. 5 is a schematic plan view of an acoustic wave device of a first reference example.

FIG. 6 is a schematic plan view of an acoustic wave device of a second reference example.

FIG. 7 is a diagram illustrating impedance frequency characteristics in the first example embodiment, the first reference example, and the second reference example of the present invention.

FIG. 8 is a diagram illustrating a relationship between a frequency and a Q factor in the first example embodiment, the first reference example, and the second reference example of the present invention.

FIG. 9 is a diagram illustrating a reverse-velocity surface of an acoustic wave propagating through a first piezoelectric substrate and a second piezoelectric substrate.

FIG. 10 is a diagram illustrating reverse-velocity surfaces of a longitudinal wave, a fast transversal wave, and a slow transversal wave in the first piezoelectric substrate.

FIG. 11 is a diagram illustrating a relationship between an absolute value of an excitation angle|θ_{c1_prop}| and a duty ratio of the IDT electrode in the first example embodiment and first and second modified examples thereof of the present invention.

FIG. 12 is a schematic plan view for describing a configuration of the IDT electrode when the fixed point is the center of gravity of two foci of an ellipse.

FIG. 13 is a schematic plan view of an acoustic wave device according to a second example embodiment of the present invention.

FIG. 14 is a diagram illustrating the impedance frequency characteristics in the second example embodiment and a third reference example of the present invention.

FIG. 15 is a diagram illustrating the relationship between the frequency and the Q factor in the second example embodiment and the third reference example of the present invention.

FIG. 16 is a schematic plan view of an acoustic wave device according to a first modified example of the second example embodiment of the present invention.

FIG. 17 is a schematic plan view of an acoustic wave device according to a second modified example of the second example embodiment of the present invention.

FIG. 18 is a schematic plan view of an acoustic wave device according to a third modified example of the second example embodiment of the present invention.

FIG. 19 is a schematic plan view of an acoustic wave device according to a fourth modified example of the second example embodiment of the present invention.

FIG. 20 is a schematic plan view illustrating the vicinity of a first edge region and that of a second edge region of an IDT electrode in a fifth modified example of the second example embodiment of the present invention.

FIG. 21 is a schematic plan view illustrating the vicinity of a first edge region and that of a second edge region of an IDT electrode in a sixth modified example of the second example embodiment of the present invention.

FIG. 22 is a schematic plan view illustrating the vicinity of a first edge region and that of a second edge region of an IDT electrode in a seventh modified example of the second example embodiment of the present invention.

FIG. 23 is a schematic plan view illustrating the vicinity of a first electrode pattern and that of a second electrode pattern of an IDT electrode according to a third example embodiment of the present invention.

FIG. 24 is a schematic plan view illustrating the vicinity of a first electrode pattern and that of a second electrode pattern of an IDT electrode in a first modified example of the third example embodiment of the present invention.

FIG. 25 is a schematic plan view illustrating the vicinity 4 first electrode pattern and that of a second electrode pattern of an IDT electrode in a second modified example of the third example embodiment of the present invention.

FIG. 26 is a schematic plan view illustrating the vicinity of a first electrode pattern and that of a second electrode pattern of an IDT electrode in a third modified example of the third example embodiment of the present invention.

FIG. 27 is a schematic plan view illustrating the vicinity of a first electrode pattern and that of a second electrode pattern of an IDT electrode in a fourth modified example of the third example embodiment of the present invention.

FIG. 28 is a schematic plan view for describing a configuration of an IDT electrode according to a fourth example embodiment of the present invention.

FIG. 29 is a diagram illustrating the relationship between the absolute value of the excitation angle |θ_{C1_prop}| and the duty ratio of the IDT electrode in the fourth example embodiment and the first and second modified examples thereof of the present invention.

FIG. 30 is a schematic plan view of an acoustic wave device according to a third modified example of the fourth example embodiment of the present example embodiment.

FIG. 31 is a schematic plan view for describing a configuration of an IDT electrode according to a fifth example embodiment of the present invention.

FIG. 32 is a schematic plan view of an acoustic wave device according to a modified example of the fifth example embodiment of the present invention.

FIG. 33 is a schematic plan view of an acoustic wave device according to a sixth example embodiment of the present invention.

FIG. 34 is a schematic plan view for describing a configuration of an IDT electrode in the sixth example embodiment of the present invention.

FIG. 35 is a schematic plan view of an acoustic wave device according to a modified example of the sixth example embodiment of the present invention.

FIG. 36 is a schematic plan view of an acoustic wave device according to a seventh example embodiment of the present invention.

FIG. 37 is a diagram illustrating a relationship between an absolute value of an excitation angle |θ_{C1_prop}| and a change rate of electrode finger pitch Δpitch of an IDT electrode according to an eighth example embodiment of the present invention.

FIG. 38 is a diagram illustrating a relationship between an absolute value of an excitation angle |θ_{C1_prop}| and thicknesses of electrode fingers of an IDT electrode according to a ninth example embodiment of the present invention.

FIG. 39 is a schematic elevational cross-sectional view of an acoustic wave device according to a tenth example embodiment of the present invention.

FIG. 40 is a diagram illustrating a relationship of an absolute value of an excitation angle |θ_{C1_prop}| in an excitation section of a first curved region covered by a dielectric film and a thickness of the dielectric film in the tenth example embodiment of the present invention.

FIG. 41 is a diagram illustrating a relationship of an absolute value of an excitation angle |θ_{C1_prop}| in an excitation section of a first curved region covered by a dielectric film and a thickness of the dielectric film in a modified example of the tenth example embodiment of the present invention.

FIG. 42 is a schematic elevational cross-sectional view of an acoustic wave device according to an eleventh example embodiment of the present invention.

FIG. 43 is a diagram illustrating impedance frequency characteristics in the eleventh example embodiment and the second reference example of the present invention.

FIG. 44 is a diagram illustrating a relationship between a frequency and a return loss in the eleventh example embodiment and the second reference example of the present invention.

FIG. 45 is a diagram illustrating the impedance frequency characteristics in a first modified example of the eleventh example embodiment and the second reference example of the present invention.

FIG. 46 is a diagram illustrating the relationship between the frequency and the return loss in the first modified example of the eleventh example embodiment and the second reference example of the present invention.

FIG. 47 is a schematic elevational cross-sectional view of an acoustic wave device according to a second modified example of the eleventh example embodiment of the present invention.

FIG. 48 is a schematic elevational cross-sectional view of an acoustic wave device according to a third modified example of the eleventh example embodiment of the present invention.

FIG. 49 is a schematic elevational cross-sectional view of an acoustic wave device according to a fourth modified example of the eleventh example embodiment of the present invention.

FIG. 50 is a schematic elevational cross-sectional view of an acoustic wave device according to a twelfth example embodiment of the present invention.

FIG. 51 is a schematic elevational cross-sectional view of an acoustic wave device according to a first modified example of the twelfth example embodiment of the present invention.

FIG. 52 is a schematic elevational cross-sectional view of an acoustic wave device according to a second modified example of the twelfth example embodiment of the present invention.

FIG. 53 is a schematic elevational cross-sectional view of an acoustic wave device according to a third modified example of the twelfth example embodiment of the present invention.

FIG. 54 is a circuit diagram of a filter device according to a thirteenth example embodiment of the present invention.

### DETAILED DESCRIPTION OF THE EXAMPLE EMBODIMENTS

In the following, the present invention will be clarified by describing example embodiments of the present invention with reference to the drawings.

Respective example embodiments described in this specification are merely illustrative and a partial replacement or combination of configurations is possible among different example embodiments.

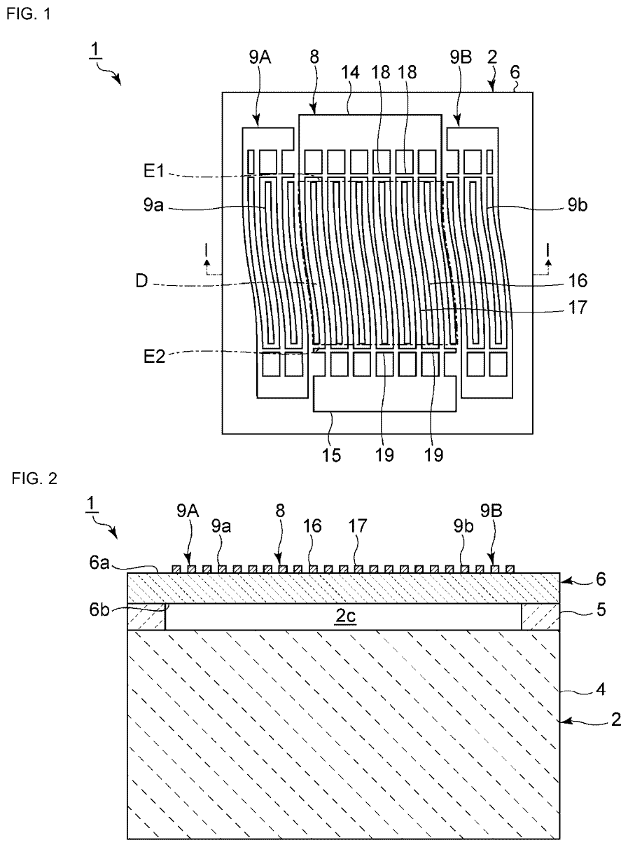

FIG. 1 is a schematic plan view of an acoustic wave device according to a first example embodiment of the present invention. FIG. 2 is a schematic cross-sectional view along I-I line in FIG. 1.

As illustrated in FIGS. 1 and 2, an acoustic wave device 1 includes a piezoelectric substrate 2. The piezoelectric substrate 2 is a substrate having piezoelectricity. Specifically, as illustrated in FIG. 2, the piezoelectric substrate 2 includes a supporting substrate 4, an intermediate layer 5, and a piezoelectric body layer 6. The intermediate layer 5 is provided on the supporting substrate 4. The piezoelectric body layer 6 is provided on the intermediate layer 5. In the present example embodiment, the intermediate layer 5 has a frame shape. That is, the intermediate layer 5 includes through-holes. The supporting substrate 4 closes one of the through-holes of the intermediate layer 5. The piezoelectric body layer 6 closes the other of the through-holes of the intermediate layer 5. As a result, a hollow portion 2c is provided in the piezoelectric substrate 2. A portion of the piezoelectric body layer 6 and a portion of the supporting substrate 4 are opposed to each other with the hollow portion 2c interposed therebetween.

The supporting substrate 4 is a supporting member in the present invention. The supporting member may be a multilayer body including the supporting substrate 4. In this case, the piezoelectric body layer 6 may be indirectly provided on the supporting substrate 4 with another layer interposed therebetween, similarly to the present example embodiment. Alternatively, the piezoelectric substrate 2 may be a substrate including only the piezoelectric body layer 6.

The piezoelectric body layer 6 includes a first main surface 6a and a second main surface 6b. The first main surface 6a and the second main surface 6b face each other. Of the first main surface 6a and the second main surface 6b, the second main surface 6b is located the supporting substrate 4 side. An IDT electrode 8 is provided on the first main surface 6a of the piezoelectric body layer 6. At least a portion of the IDT electrode 8 overlaps with the hollow portion 2c in plan view. In this specification, plan view refers to a view from a direction corresponding to an upper side of FIG. 2. In FIG. 2, for example, of the supporting substrate 4 side and the piezoelectric body layer 6 side, the upper side is the piezoelectric body layer 6 side.

As illustrated in FIG. 1, the IDT electrode 8 includes a pair of busbars and a plurality of electrode fingers. Specifically, the pair of busbars include a first busbar 14 and a second busbar 15. The first busbar 14 and the second busbar 15 are opposed to each other. Specifically, the plurality of electrode fingers include a plurality of first electrode fingers 16 and a plurality of second electrode fingers 17. One end of each of the plurality of first electrode fingers 16 is connected to the first busbar 14. One end of each of the plurality of second electrode fingers 17 is connected to the second busbar 15. Each of the plurality of first electrode fingers 16 and the plurality of second electrode fingers 17 includes a base end portion and a tip portion. The base end portion of the first electrode finger 16 is connected to the first busbar 14. The base end portion of the second electrode finger 17 is connected to the second busbar 15. The plurality of first electrode fingers 16 and the plurality of second electrode fingers 17 are interdigitated with each other. In the following, the first electrode fingers 16 and the second electrode fingers 17 may be simply referred to as electrode fingers. The first busbar 14 and the second busbar 15 may be simply referred to as busbars.

In the IDT electrode 8 of the acoustic wave device 1, the electrode finger pitch is constant. The electrode finger pitch is a center-to-center distance between the first electrode finger 16 and the second electrode finger 17 that are adjacent to each other. When the electrode finger pitch is p, a wavelength A defined by the electrode finger pitch p is λ=2p.

The IDT electrode 8 includes a plurality of first electrode patterns 18 and a plurality of second electrode patterns 19. More specifically, the plurality of first electrode patterns 18 are each located between the first busbar 14 and the second electrode fingers 17. On the other hand, the plurality of second electrode patterns 19 are each located between the second busbar 15 and the first electrode fingers 16. In the following, the first electrode patterns 18 and the second electrode patterns 19 may be simply referred to as electrode patterns.

Each of the plurality of first electrode patterns 18 is connected to both of first electrode fingers 16 that are adjacent to each other. The plurality of first electrode patterns 18 have a rectangular or substantially rectangular shape extending parallel or substantially parallel to the first busbar 14 in plan view. Then, in the present example embodiment, the first electrode patterns 18 are each provided between all of the first electrode fingers 16. Therefore, a configuration of the IDT electrode 8 corresponds to a configuration in which all of the first electrode fingers 16 are connected by the first busbar 14 and bar-shaped electrodes other than the first busbar 14. In the present example embodiment, the first busbar 14, the plurality of first electrode fingers 16, and the plurality of first electrode patterns 18 define a plurality of cavities. However, the plurality of first electrode patterns 18 do not have to be connected to the first electrode fingers 16.

Each of the plurality of second electrode patterns 19 is connected to both of second electrode fingers 17 that are adjacent to each other. The plurality of second electrode patterns 19 have a rectangular or substantially rectangular shape extending parallel or substantially parallel to the second busbar 15 in plan view. In the present example embodiment, the second electrode patterns 19 are each provided between all of the second electrode fingers 17. Then, the second busbar 15, the plurality of second electrode fingers 17, and the plurality of second electrode patterns 19 define the plurality of cavities. However, the plurality of second electrode patterns 19 do not have to be connected to the second electrode fingers 17.

As illustrated in FIG. 1, each of the first electrode patterns 18 is opposed to the first busbar 14 with a gap therebetween. In addition, each of the second electrode patterns 19 is opposed to the second busbar 15 with a gap therebetween.

In the acoustic wave device 1, all of the first electrode patterns 18 are each opposed to the tip portions of the second electrode fingers 17 with a gap therebetween. All of the second electrode patterns 19 are each opposed to the tip portions of the first electrode fingers 16 with a gap therebetween. It is sufficient that, among the plurality of electrode fingers, the tip portion of at least one of the first electrode fingers 16 or the tip portion of at least one of the second electrode fingers 17 faces the electrode pattern.

Specifically, it is sufficient that the acoustic wave device 1 has at least one of a configuration in which the tip portion of the at least one of the first electrode fingers 16 faces the second electrode pattern 19 and a configuration in which the tip portion of the at least one of the second electrode fingers 17 faces the first electrode pattern 18. For example, it is sufficient that the first electrode pattern 18 is provided between at least one set of the adjacent first electrode fingers 16. It is sufficient that at least one of the first electrode patterns 18 faces at least one the of second electrode fingers 17. Alternatively, for example, it is sufficient that the second electrode pattern 19 is provided between at least one set of the adjacent second electrode fingers 17. It is sufficient that at least one of the second electrode patterns 19 faces at least one of the first electrode fingers 16.

An imaginary line connecting the tip portions of the plurality of second electrode fingers 17 is a first envelope E1, and an imaginary line connecting the tip portions of the plurality of first electrode fingers 16 is a second envelope E2. A region between the first envelope E1 and the second envelope E2 is an intersecting region D. More specifically, a region surrounded by, among the plurality of electrode fingers, the electrode finger at one end in a direction in which the plurality of electrode fingers are arranged, the electrode finger at other end, the first envelope E1, and the second envelope E2 is the intersecting region D. Thus, the first envelope E1 corresponds to an edge portion on the first busbar 14 side in the intersecting region D. The second envelope E2 corresponds to an edge portion on the second busbar 15 side in the intersecting region D. In the intersecting region D, when viewed from the direction in which the electrode fingers are arranged, that is, a direction in which the first envelope E1 or the second envelope E2 extends, the adjacent electrode fingers overlap each other. It is sufficient that the electrode pattern is provided in at least one of between the first busbar 14 and the intersecting region D and between the second busbar 15 and the intersecting region D.

In the present example embodiment, shapes of the plurality of first electrode fingers 16 and the plurality of second electrode fingers 17 in plan view include a shape in which two arcs are connected, and more specifically, include a shape in which arcs of two circles are connected, centers of which are at different locations and which have the same or substantially the same radius. The centers of the above two circles are opposed to each other with the IDT electrode 8 interposed therebetween. However, the shape of the plurality of electrode fingers is not limited to the above. It is sufficient that the shape of the plurality of electrode fingers in plan view includes a curved shape in the intersecting region D.

According to the present example embodiment: 1) the shapes of the plurality of first electrode fingers 16 and the plurality of second electrode fingers 17 in plan view each include a curved portion in the intersecting region D; and 2) a distance between the tip portion of the electrode finger of the plurality of electrode fingers that faces the electrode pattern and the electrode pattern is about 0.5λ or less. This improves the Q factor. Details of advantageous effects of the above are described below, along with details of the configuration of the IDT electrode 8.

As illustrated in FIG. 1, the shapes of the plurality of first electrode fingers 16 and the plurality of second electrode fingers 17 in plan view each include an inflection point. In this specification, the inflection point refers to a point at which mutually different curved lines are connected or a point to which a curved line and a straight line are connected. When mutually different curved lines are connected at an inflection point, directions of the curved shapes differ from the inflection point as a boundary. The directions of the curved shapes differing from each other means that, in the curved shapes, for example, the directions of bending differ from one another. More specifically, for example, in FIG. 1, the directions of curved shapes differ between a case where the curved shape is bent to project in a left direction and a case where the curved shape is bent to project in a right direction. In the present example embodiment, the two curved shapes are inverted with respect to each other with the inflection point as a boundary.

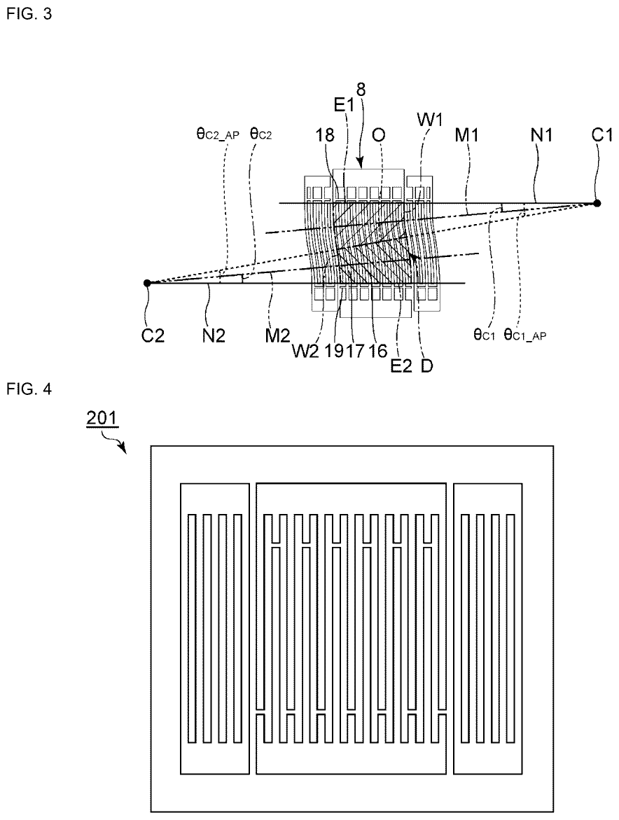

FIG. 3 is a schematic plan view for describing a configuration of the IDT electrode in the first example embodiment. In FIG. 3, each curved region to be described below is illustrated with hatching.

As described above, the plurality of electrode fingers each have the shape in plan view in which the two arcs are connected. In plan view, one of the arcs in the shapes of the plurality of electrode fingers is an arc of each of a plurality of concentric circles. Therefore, the centers of the circles including the arcs in shapes of the plurality of electrode fingers are coincident. In the present example embodiment, these centers of the circles are denoted as fixed point C1. In plan view, other arcs in the shapes of the plurality of electrode fingers are each also arcs of the plurality of concentric circles. These centers of the circles are denoted as fixed point C2. In this manner, in the present example embodiment, the two fixed points C1 and C2 are defined. The fixed points C1 and C2 are opposed to each other with the IDT electrode 8 interposed therebetween.

It is possible to define the direction of the curved shape depending on whether the shape of the electrode finger in plan view is the arc centered on the fixed point C1 or the arc centered on the fixed point C2. However, the IDT electrode 8 may have a shape, for example, in which three or more fixed points are defined.

The shapes of the plurality of electrode fingers in plan view may include an elliptical arc, for example. In this case, the fixed points are midpoints between two foci of an ellipse including the elliptical arc. In other words, the fixed point is a center of gravity of the two foci of the ellipse. Alternatively, for example, mutually different portions of the curved shapes in the plurality of electrode fingers in plan view may be, for example, a combination of an arc and an elliptical arc.

Here, an ellipse coefficient of the shape of the plurality of electrode fingers in plan view is α2/α1. In the present example embodiment, since the shape of each of the electrode fingers includes two arcs, the two ellipse coefficients α2/α1 can be defined. Specifically, in the shapes of the plurality of electrode fingers, the ellipse coefficient of a circle or an ellipse based on the fixed point C1 is α12/α11, and the ellipse coefficient of a circle or an ellipse based on the fixed point C2 is α22/α21. The ellipse coefficients α12/α11 and α22/α21 in the present example embodiment are both about 1, for example. When the shape including an arc in the plurality of electrode fingers is an ellipse, the ellipse coefficients α12/α11 and α22/α21 are other than 1. α1, that is, α11 and α21, corresponds to a dimension along a direction of either of a major axis and a minor axis of the ellipse that passes through the intersecting region D. α2, that is, α12 and α22, corresponds to a dimension along a direction of either of the major axis and the minor axis of the ellipse that does not pass through the intersecting region D.

When r1 is any constant, an expression of the ellipse coefficient in an xy plane can be expressed as (x/α11)²+(y/α12)²=r1². Similarly, when r2 is any constant, the expression of the ellipse coefficient in the xy plane can be expressed as (x/α21)²+(y/α22)²=r2².

As illustrated in FIG. 3, the intersecting region D includes a plurality of curved regions. Specifically, in the present example embodiment, the plurality of curved regions include a first curved region W1 and a second curved region W2. The first curved region W1 includes the first envelope E1. The second curved region W2 includes the second envelope E2. In each curved region, the plurality of first electrode fingers 16 and the plurality of the second electrode fingers 17 each include a single arc or elliptical arc shape when viewed in plan. A boundary line between the mutually different curved regions corresponds to a line connecting the inflection points of the respective electrode fingers. A boundary line O between the first curved region W1 and the second curved region W2 illustrated in FIG. 3 is a straight line. Then, an extended line of the boundary line O passes through the fixed point C1 and the fixed point C2. However, a configuration of the IDT electrode 8 in the present example embodiment is merely an example, and the extended line of the boundary line O does not have to pass through the fixed point C1 and the fixed point C2.

Application of an alternating-current voltage to the IDT electrode 8 excites acoustic waves in the intersecting region D. The first curved region W1 in the intersecting region D includes respective portions located on an infinite number of straight lines passing through the fixed point C1. FIG. 3 illustrates a straight line M1, as an example of the infinite number of straight lines passing through the fixed point C1 and the first curved region W1. For example, in a portion located on the straight line M1 in the first curved region W1, an acoustic wave is excited. An acoustic wave is also excited in each of portions located on an infinite number of unillustrated straight lines passing through the fixed point C1 and the first curved region W1. Specifically, the acoustic wave device 1 includes an excitation section located on the straight line M1 and an excitation section located on an infinite number of other unillustrated straight lines.

Similarly, the second curved region W2 in the intersecting region D includes an infinite number of excitation sections. An excitation section in the second curved region W2 is located on a straight line passing through the fixed point C2. FIG. 3 illustrates a straight line M2, as an example of an infinite number of straight lines passing through the fixed point C2 and the second curved region W2.

An extended line of the first envelope E1 passes through the fixed point C1. In the acoustic wave device 1, a straight line including the first envelope E1 and the extended line of the first envelope E1 is defined as a reference line N1 in the first curved region W1. Then, an angle between a straight line passing through the fixed point C1 and the excitation section in the first curved region W1 and the reference line N1 is defined as an angle θ_{C1} in the first curved region W1. FIG. 3 illustrates the angle θ_{C1} of the excitation section located on the straight line M1, as an example. The angle θ_{C1} is about 0° in the first envelope E1, for example.

On the other hand, an extended line of the second envelope E2 passes through the fixed point C2. A straight line including the second envelope E2 and the extended line of the second envelope E2 is defined as a reference line N2 in the second curved region W2. An angle between a straight line passing through the fixed point C2 and an excitation section in the second curved region W2 and the reference line N2 is defined as an angle θ_{C2} in the second curved region W2. FIG. 3 illustrates the angle θ_{C2} of the excitation section located on the straight line M2, as an example. The angle θ_{C2} is about 0° in the second envelope E2, for example.

In this specification, unless otherwise specified, a positive direction of the angle θ_{C1} is a counterclockwise direction when viewed in plan view. More specifically, a direction from the second busbar 15 side toward the first busbar 14 side is the above positive direction. A positive direction of the angle θ_{C2} is also the counterclockwise direction when viewed in plan view.

Meanwhile, a direction in which an acoustic wave is excited is any of the following three types. A first type of direction is a perpendicular direction or substantially perpendicular to a direction in which the electrode fingers extend. A second type of direction is a direction connecting the shortest distance between the adjacent electrode fingers. A third type of direction is a direction parallel or substantially parallel to an electric field vector generated between the electrode fingers.

Each of the electrode fingers includes a pair of edge portions connecting the base end portion and the tip portion in plan view. Then, both of the edge portions have a curved shape. In this specification, unless otherwise specified, the direction in which the electrode fingers extend is as follows. First, if an imaginary line parallel or substantially parallel to the reference line in the present invention is drawn in any portion of the electrode finger so as to connect both of the edge portions, the center of gravity of the portion located on the imaginary line is defined as a representative point in the imaginary line. In the electrode finger, an infinite number of imaginary lines can be drawn and an infinite number of representative points exist. A direction in which a line tangent to a curved line connecting these representative points extends is defined as the direction in which the electrode fingers extend. The direction in which the electrode fingers extend varies for each position in the electrode fingers. In a case where there is a different reference line for each curved region as in the present example embodiment, the reference line in the curved region where an imaginary line is drawn may be set as a direction in which the imaginary line extends.

As illustrated in FIG. 4, in an acoustic wave device 201 in the related art, an excitation direction of the acoustic wave is the same or substantially the same in all of the three types of directions described above. In contrast, in the present example embodiment illustrated in FIG. 3, in each of the curved regions, the shape of the electrode finger in plan view is the arc centered on each of the fixed points. In this case, the direction in which the acoustic wave is excited is the first type of direction described above. That is, the direction in which the acoustic wave is excited is represented by a direction perpendicular or substantially perpendicular to the direction in which the electrode fingers extend.

An angle between the reference line N1 and the excitation direction of the acoustic wave at the intersection between a straight line passing through the fixed point C1 and the excitation section in the first curved region W1 and the electrode fingers is defined as an excitation angle θ_{C1_prop}. On the other hand, an angle between the reference line N2 and the excitation direction of the acoustic wave at the intersection between a straight line passing through the fixed point C2 and the excitation section in the second curved region W2 and the electrode fingers is defined as an excitation angle θ_{C2_prop}. Positive and negative directions of the excitation angle θ_{C1_prop} and the excitation angle θ_{C2_prop} are the same as positive and negative directions of the angle θ_{C1} and the angle θ_{C2}, respectively.

Here, the angle θ_{C1} in the excitation section of the first curved region W1 and the excitation angle θ_{C1_prop} are approximately coincident. In the following, details of the configurations of example embodiments of the present invention may be described by referring to either one of the angle θ_{C1} and the excitation angle θ_{C1_prop}. However, it is to be pointed out that there is no influential difference between the angle θ_{C1} and the excitation angle θ_{C1_prop}. A relationship between the angle θ_{C2} in the excitation section of the second curved region W2 and the excitation angle θ_{C2_prop} is also the same or similar. If the shape of the electrode finger in plan view is an arc in each of the curved regions and the ellipse coefficient α2/α1 is about 1, the angle θ_{C1} and the excitation angle θ_{C1_prop} are equal or substantially equal. Similarly, the angle θ_{C2} and the excitation angle θ_{C2_prop} are also equal or substantially equal.

In each of the curved regions, an angle between the straight line passing through the edge portion on the first busbar 14 side and the fixed point C1, and a straight line passing through the edge portion on the second busbar 15 side and the fixed point C2 is defined as an intersecting angle. The intersecting angle in the first curved region W1 is defined as θ_{C1_AP} and the intersecting angle in the second curved region W2 is defined as θ_{C2_AP}. More specifically, in the present example embodiment, the straight line passing through the edge portion on the first busbar 14 side and the fixed point C1 in the first curved region W1 is the reference line N1 that is the straight line passing through the first envelope E1 and the fixed point C1. On the other hand, as described above, the extended line of the boundary line O of the first curved region W1 and the second curved region W2 passes through the fixed point C1 and the fixed point C2. Thus, the straight line passing through the edge portion on the second busbar 15 side in the first curved region W1 and the fixed point C1 is a straight including the boundary line O. Therefore, the intersecting angle θ_{C1_AP} in the first curved region W1 is an angle between the reference line N1 and the straight line including the boundary line O. In this case, 0≤θ_{C1_prop}≤θ_{C1_AP}.

On the other hand, the intersecting angle θ_{C2_AP} in the second curved region W2 is an angle between the reference line N2 and the straight line including the boundary line O. In this case, 0≤θ_{C2_prop}≤θ_{C2_AP}. In the acoustic wave device 1, the intersecting angle θ_{C1_AP} of the first curved region W1 is the same or substantially the same as the intersecting angle θ_{C2_AP} of the second curved region W2. However, the intersecting angle θ_{C1_AP} of the first curved region W1 and the intersecting angle θ_{C2_AP} of the second curved region W2 may differ from each other.

As described above, in the IDT electrode 8 of the acoustic wave device 1, the electrode finger pitch is constant. Therefore, the wavelength A in the IDT electrode 8 is constant irrespective of the excitation angle θ_{C1_prop} and the excitation angle θ_{C2_prop}.

A piezoelectric single crystal is used as a material for the piezoelectric body layer 6 of the acoustic wave device 1. In the piezoelectric body layer 6, a propagation axis is an axis through which an acoustic wave propagates. A direction in which the propagation axis extends is an X-propagation direction. In the present example embodiment, among the straight lines passing through the intersecting region D and the fixed point C1 or the fixed point C2, straight lines that extend parallel or substantially parallel to the propagation axis are the reference line N1 and the reference line N2. However, the reference line N1 and the reference line N2 do not necessarily have to extend parallel or substantially parallel to the propagation axis.

The direction in which the propagation axis extends may be a direction perpendicular or substantially perpendicular to any of a 90° X-propagation direction or a direction in which the electrode fingers of the IDT electrode 8 extend, in addition to the X-propagation direction.

As illustrated in FIG. 1, a pair of a reflector 9A and a reflector 9B are provided on the piezoelectric body layer 6. The reflector 9A and the reflector 9B are opposed to each other with the IDT electrode 8 interposed therebetween, in a direction in which the plurality of electrode fingers of the IDT electrode 8 are arranged. The reflector 9A includes a plurality of reflector electrode fingers 9a. The reflector 9B includes a plurality of reflector electrode fingers 9b. In plan view, a shape of the plurality of reflector electrode fingers 9a of the reflector 9A and a shape of the plurality of reflector electrode fingers 9b of the reflector 9B each include a curved shape.

More specifically, in the present example embodiment, in plan view, the shape of the plurality of reflector electrode fingers 9a of the reflector 9A and the shape of the plurality of reflector electrode fingers 9b of the reflector 9B each are a shape in which two arcs are connected. In plan view, one of arcs in the shapes of the plurality of reflector electrode fingers 9a is each an arc of a plurality of concentric circles centered on the fixed point C1. In plan view, other arcs in the shapes of the plurality of reflector electrode fingers 9a are each arcs of a plurality of concentric circles centered on the fixed point C2. The same applies to the shape of the plurality of reflector electrode fingers 9b. The shape of each of the reflector electrode fingers corresponds to the shape of the electrode finger of the IDT electrode 8 in the excitation section. The shape of each of the reflector electrode fingers in plan view may be a curved shape or a linear shape that does not correspond to the shape of the electrode finger of the IDT electrode 8 in the excitation section.

An advantageous effect of the first example embodiment of increasing the Q factor are described below. This advantageous effect is described by a comparison of the first example embodiment with a first reference example and a second reference example.

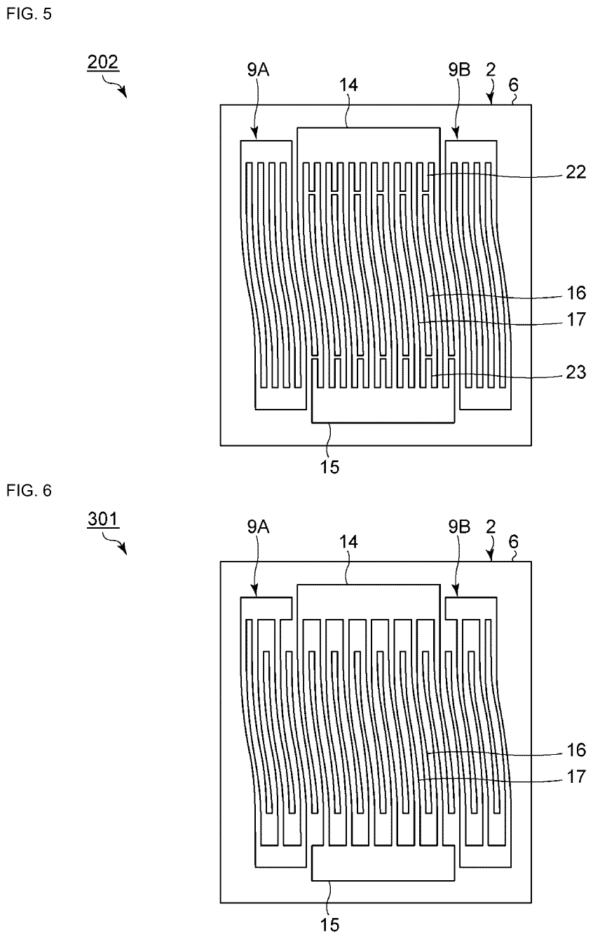

An acoustic wave device 202 of the first reference example illustrated in FIG. 5 differs from the acoustic wave device 1 of the first example embodiment in that the acoustic wave device 202 includes no electrode patterns according to the first example embodiment of the present invention and that the acoustic wave device 202 includes a plurality of first offset electrodes 22 and a plurality of second offset electrodes 23.

More specifically, in the acoustic wave device 202, one end of each of the plurality of first offset electrodes 22 is connected to the first busbar 14. The first electrode fingers 16 and the first offset electrodes 22 are arranged alternately. One end of each of the plurality of second offset electrodes 23 is connected to the second busbar 15. The second electrode fingers 17 and the second offset electrodes 23 are arranged alternately.

Similarly to the plurality of electrode fingers, the plurality of first offset electrodes 22 and the plurality of second offset electrodes 23 each include a base end portion and a tip portion. The base end portion of the first electrode finger 16 and that of the first offset electrode 22 are portions connected to the first busbar 14. The base end portion of the second electrode finger 17 and that of the second offset electrode 23 are portions connected to the second busbar 15. The tip portion of the first electrode finger 16 is opposed to the tip portion of the second offset electrode 23 with a gap therebetween. On the other hand, the tip portion of the second electrode finger 17 is opposed to the tip portion of the first offset electrode 22 with a gap therebetween. In the following, the first offset electrodes 22 and the second offset electrodes 23 may be simply referred to as offset electrodes.

An acoustic wave device 301 of the second reference example illustrated in FIG. 6 differs from the acoustic wave device 1 of the first example embodiment in that the acoustic wave device 301 includes no electrode patterns according to the first example embodiment of the present invention. Design parameters of the acoustic wave device 1 of the first example embodiment according to the comparison are as follows. Here, a distance between the tip portion of the electrode finger facing the electrode pattern and the electrode pattern is defined as an I-P gap. A distance between the electrode pattern and the busbar is defined as a B−P gap. A dimension of the electrode pattern along a direction perpendicular to a direction in which the electrode patterns extends is defined as a width of the electrode pattern.

Supporting substrate 4; Material . . . Si, plane orientation . . . (111), ψ at Euler angles (φ, θ, and ψ): about 73°
Intermediate layer 5; Material . . . SiO₂, thickness . . . about 0.15λ
Piezoelectric body layer 6; Material . . . Rotated Y-cut 55° X-propagation LiTaO₃, thickness . . . about 0.2λ
IDT electrode 8; Material . . . Al, thickness . . . about 0.05λ
Ellipse coefficient in the shape of the electrode finger α12/α11; about 1
Ellipse coefficient in the shape of the electrode finger α22/α21; about 1
Wavelength λ; about 2 μm
Number of pairs of the electrode fingers of the IDT electrode 8; 100 pairs
Duty ratio; about 0.5 in the excitation section where the angle θ_{C1} and the angle θ_{C2} are about 0°
Intersecting angle θ_{C1_AP}; about 10°
Intersecting angle θ_{C2_AP}; about 10°
I-P gap; about 0.135λ
Width of the first electrode pattern 18 and the second electrode pattern 19; about 0.2λ
B-P gap; about 3.2λ
Reflector 9A and reflector 9B; number of pairs of the reflector electrode fingers . . . 20 pairs

The design parameters of the acoustic wave devices of the first reference example and the second reference examples are the same as or similar to the design parameters of the acoustic wave device 1 described above, except for parameters related to the electrode patterns. In the first reference example, when a dimension of the offset electrode along a direction connecting the base end portion and the tip portion is defined as a length of the offset electrode, the length of each of the offset electrodes is about 3.5λ. In the second reference example, the distance between the electrode finger and the busbar is about 3.5λ.

Impedance frequency characteristics and a relationship between the frequency and the Q factor of the respective acoustic wave devices of the first example embodiment, the first reference example, and the second reference example are determined.

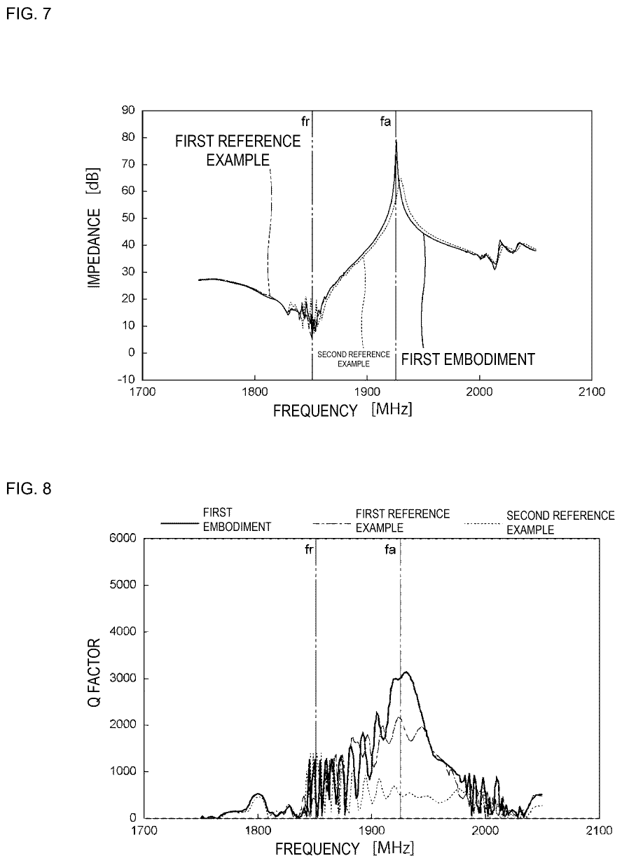

FIG. 7 is a diagram illustrating the impedance frequency characteristics in the first example embodiment, the first reference example, and the second reference example. FIG. 8 is a diagram illustrating the relationship between the frequency and the Q factor in the first example embodiment, the first reference example, and the second reference example. Note that in FIGS. 7 and 8, fr is a resonant frequency and fa is an anti-resonant frequency.

As illustrated in FIG. 7, in the first reference example and the second reference example, the impedance frequency characteristics are substantially the same. On the other hand, it can be seen that an impedance ratio is larger in the first example embodiment than in the first reference example and the second reference example.

As illustrated in FIG. 8, it can be seen that the Q factor is higher in the first example embodiment than in the first reference example and the second reference example. Specifically, in the first example embodiment, the Q factor is high around the anti-resonant frequency, in particular. Due to this, the impedance at the anti-resonant frequency is high in the first example embodiment. As a result of this, the impedance ratio in the first example embodiment can be made large.

Leakage of energy of acoustic waves occurs, for example, with mode conversion. For example, when SH waves are used as a main mode of an acoustic wave, the energy of the acoustic wave leaks, due to conversion from the SH wave to a Rayleigh wave or conversion from the SH wave to a bulk wave. Such leakage occurs from the intersecting region side toward the busbar side.

In the first reference example, an attempt to reduce or prevent the leakage of acoustic wave energy is made using the offset electrode. In the first reference example, however, the leakage cannot be sufficiently reduced or prevented. In the second reference example, since no offset electrode is provided, the leakage of acoustic wave energy is not reduced or prevented as compared to the first reference example. Therefore, in the first reference example and the second reference example, the Q factor cannot be increased sufficiently.

In contrast to these, in the first example embodiment illustrated in FIG. 1, the first electrode patterns 18 are provided between the first busbar 14 and the second electrode fingers 17. Similarly, the second electrode patterns 19 are provided between the second busbar 15 and the first electrode fingers 16. In addition, the I-P gap, which is the distance between the tip portion of the electrode finger facing the electrode pattern and the electrode pattern, is set to about 0.5λ or less. The leakage of acoustic wave energy due to the mode conversion.

In addition, in the first example embodiment, the plurality of first electrode patterns 18 is opposed to the first busbar 14 with a gap therebetween. Then, in the intersecting region D, the first electrode fingers 16 and the second electrode fingers 17 are arranged alternately, while in the region closer to the first busbar 14 side than the plurality of first electrode patterns 18, only the first electrode fingers 16 of the first electrode fingers 16 and the second electrode fingers 17 are provided. This provides a high acoustic velocity region in a region between the plurality of first electrode patterns 18 and the first busbar 14. A high acoustic velocity region is a region where the acoustic velocity is higher than that in a central region. The central region is a region located at the center in the intersecting region D. The central region is described below in detail. A high acoustic velocity region is also provided in a region between the plurality of second electrode patterns 19 and the second busbar 15.

An arrangement of the high acoustic velocity regions on the first busbar 14 side and the second busbar 15 side makes it possible to effectively confine the acoustic wave energy to the intersecting region D side. Therefore, in the first example embodiment, the Q factor can be effectively increased.

When the I-P gap exceeds about 0.5λ, the energy starts to leak to outside of the intersecting region. When the I-P gap exceeds about 1λ, the effect of reducing or preventing the leakage of acoustic wave energy can no longer be obtained. On the other hand, it is seen that the smaller a value of the I-P gap, the higher the Q factor and the larger the impedance ratio. Then, when the I-P gap is about 0.5\ or less, the Q factor and the impedance ratio are the same or substantially the same. Therefore, by having the I-P gap of about 0.5λ or less, the Q factor can be increased effectively, and the impedance ratio can be made large.

In the following, further details of the present example embodiment are described.

In the first curved region W1, the angle θ_{C1} and the excitation angle θ_{C1_prop} are about 0° in the excitation section through which the reference line N1 passes. In the second curved region W2, the angle θ_{C2} and the excitation angle θ_{C2_prop} are about 0° in the excitation section through which the reference line N2 passes. Between the respective excitation sections in the respective curved regions, the excitation angle θ_{C1_prop} or the excitation angle θ_{C2_prop} differ from each other, and thus the propagation characteristics of acoustic waves differ from each other. In contrast to this, in the present example embodiment, the duty ratios are made to differ from each other in the plurality of excitation sections, so that the resonant frequencies or the anti-resonant frequencies in all of the excitation approximately coincide with each other. The duty ratios are the same or substantially the same between the excitation sections where absolute value of the excitation angle |θ_{C1_prop}| or |θ_{C2_prop}| is the same or substantially the same. Since the IDT electrode 8 is configured as described above, resonance characteristics are less likely to deteriorate. However, the duty ratios may be constant.

In this specification, one frequency being approximately coincident with another frequency means that an absolute value of a difference between the two frequencies is, for example, about 10% or less with respect to a reference frequency. The reference frequency refers to a frequency when the excitation angle is about 0°. In the intersecting region D, an absolute value of a difference between the highest resonant frequency and the lowest resonant frequency in the main mode is, for example, preferably about 2% or less with respect to the reference frequency, and more preferably about 1% or less. Alternatively, in the intersecting region D, an absolute value of a difference between the highest anti-resonant frequency and the lowest anti-resonant frequency in the main mode is, for example, preferably about 2% or less with respect to the reference frequency and more preferably, about 1% or less. As a result, the resonance characteristics can be improved more reliably.

In the first example embodiment, advantageous effects such as reduction or prevention of spurious waves can be obtained by utilizing the propagation characteristics of acoustic waves that differ from each other in each of the excitation sections, details of which are described below.

A phase velocity of an acoustic wave has a dependency on the excitation angle in each of the curved regions, and has a unique characteristic according to a substrate configuration. A reciprocal number of the phase velocity corresponds to a reverse-velocity surface. Therefore, a relationship between the excitation angle θ_{C1_prop}, the excitation angle θ_{C2_prop}, and the phase velocity is equal or approximately equal to the reverse-velocity surface of the piezoelectric substrate. Now, an example of the reverse-velocity surface of piezoelectric substrates having different layer configurations from each other is described. One of the piezoelectric substrates is, for example, a substrate including only rotated Y-cut 42° X-propagation LiTaO₃ (LT). This substrate is defined as a first piezoelectric substrate. The other piezoelectric substrate is a laminated substrate including the piezoelectric body layer/supporting substrate. This substrate is defined as a second piezoelectric substrate. More specifically, for example, the second piezoelectric substrate is a substrate in which a silicon substrate with a plane orientation of (100), a silicon oxide film, and lithium tantalate layer are laminated in this order. Even when the silicon substrate has any other plane orientation such as (110) or (111), shapes of irregularities of the reverse-velocity surface do not change.

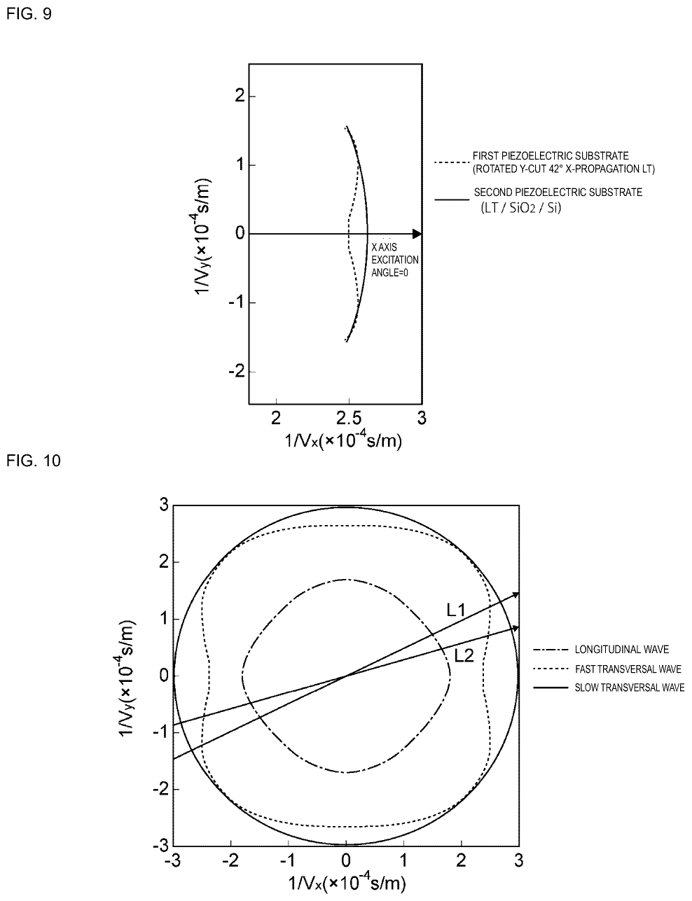

FIG. 9 is a diagram illustrating a reverse-velocity surface of an acoustic wave propagating through the first piezoelectric substrate and the second piezoelectric substrate.

The x-axis illustrated in FIG. 9 corresponds to the result when being parallel or substantially parallel to the propagation axis. That is, the x-axis corresponds to the result when the excitation angle θ_{C1_prop} and the excitation angle θ_{C2_prop} are about 0°. The reverse-velocity surfaces in the first piezoelectric substrate and the second piezoelectric substrate are both line-symmetric with the x-axis as a symmetric axis. The reverse-velocity surface in the first piezoelectric substrate is concave-shaped. On the other hand, the reverse-velocity surface in the second piezoelectric substrate is convex-shaped. As such, it can be seen that the dependency of the acoustic wave propagating through the substrate on the excitation angle θ_{C1_prop} and the excitation angle θ_{C2_prop} varies depending on the substrate configuration. Furthermore, when the acoustic wave mode is different, the dependency on the excitation angle θ_{C1_prop} and the excitation angle θ_{C2_prop} in a same substrate differs. This is described in FIG. 10.

FIG. 10 is a diagram illustrating reverse-velocity

surfaces of a longitudinal wave, a fast transversal wave, and a slow transversal wave in the first piezoelectric substrate.

As illustrated in FIG. 10, the reverse-velocity surfaces of three types of acoustic wave modes, which are the longitudinal wave, the fast transversal wave, and the slow transversal wave, differ from each other. Portions passing through arrows L1 and L2 in FIG. 10 each correspond to an example of results when the excitation angle θ_{C1_prop} and the excitation angle θ_{C2_prop} are other than 0°. An interval between the reverse-velocity surfaces of the slow transversal wave and the fast transversal wave in the portion passing through the arrow L1 is different from an interval between the reverse-velocity surfaces of the slow transversal wave and the fast transversal wave in the portion passing through the arrow L2. Similarly, an interval between the reverse-velocity surfaces of the fast transversal wave and the longitudinal wave in the portion passing through the arrow L1 is different from an interval between the reverse-velocity surfaces of the fast transversal wave and the longitudinal wave in the portion passing through the arrow L2. That is, in each of the curved regions, the intervals of the reverse-velocity surfaces of the different modes are different between the excitation sections having mutually different excitation angles. This also applies to a relationship between the main mode and the spurious waves used in the acoustic wave device.

In this case, in the acoustic wave device 1 of the first example embodiment, the resonant frequencies or the anti-resonant frequencies in the main mode are approximately coincident with each other in all of the excitation sections. Therefore, in the different excitation sections, frequencies of the spurious waves differ from each other. As a result, spurious waves outside of pass band are dispersed. Therefore, the spurious waves outside of the pass band can be reduced or prevented. In this specification, frequencies outside of the pass band in the acoustic wave device refer to frequencies on the lower side than the resonant frequency and frequencies on the higher side than the anti-resonant frequency.

In the first example embodiment, since the resonant frequencies or the anti-resonant frequencies in each of the excitation sections are approximately coincident with each other, the main mode is preferably excited. Therefore, deterioration of the resonance characteristics can be reduced or prevented more reliably.

In addition, as illustrated in FIG. 3, in the first example embodiment, the intersecting region D includes the first curved region W1 and the second curved region W2. This makes it possible to effectively increase the intersecting angle at any position of the acoustic wave device 1. More specifically, each of the electrode fingers includes a portion located in the first curved region W1 and a portion located in the second curved region W2. Therefore, the intersecting angle at a position where each of the electrode fingers is located corresponds to a sum of the intersecting angle θ_{C1_AP} in the first curved region W1 and the intersecting angle θ_{C2_AP} in the second curved region W2. As a result, a range of the excitation angles is wide at any position in the intersecting region D. This makes it possible to effectively disperse the spurious waves and a transverse mode outside of the pass band.

As described above, the phase velocity corresponds to the reciprocal number of the reverse-velocity surface. Therefore, the relationship between the excitation angle θ_{C1_prop}r the excitation angle θ_{C2_prop}, and the phase velocity is approximately equal to the reverse-velocity surface in the XY plane of the piezoelectric substrate as illustrated in FIG. 10. In other words, it can be said that the shape of the reverse-velocity surface in the XY plane of the piezoelectric substrate dictates a function representing the curved shape of the electrode finger. The phase velocity of the acoustic wave has a dependency on the excitation angle θ_{C1_prop} and the excitation angle θ_{C2_prop}.

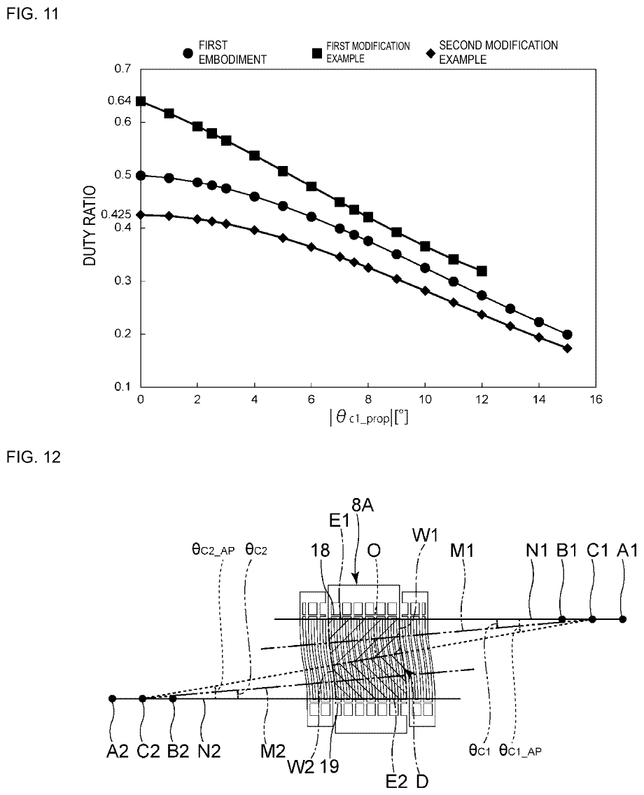

In the first example embodiment, by varying the duty ratio according to the excitation angle θ_{C1_prop} and the excitation angle θ_{C2_prop} in each of the curved region, the resonant frequencies or the anti-resonant frequencies in all of the excitation sections are made approximately coincident with each other. FIG. 11 illustrates a relationship between the excitation angle θ_{C1_prop} and the duty ratio in the first example embodiment. Examples in which the maximum value of the duty ratio differs from that of the first example embodiment are also illustrated as a first modified example and a second modified example of the first example embodiment.

FIG. 11 is a diagram illustrating a relationship between the absolute value of the excitation angle |θ_{C1_prop}| and the duty ratio of the IDT electrode in the first example embodiment, the first modified example, and the second modified example.

In the first example embodiment, the duty ratio is set to the maximum value, when the excitation angle θ_{C1_prop} is about 0°. In the first example embodiment, for example, when the excitation angle θ_{C1_prop} is about 0°, the duty ratio is about 0.5. Then, the larger the absolute value of the excitation angle |θ_{C1_propl}, the smaller the duty ratio. As a result, the resonant frequencies or the anti-resonant frequencies are approximately coincident with each other in all of the excitation sections in the first curved region.

In the first modified example and the second modified example as well, the larger the absolute value of the excitation angle |θ_{C1_prop}|, the smaller the duty ratio. In the first modified example, when the excitation angle θ_{C1_prop} is about 0°, the duty ratio is about 0.64. In the second modified example, when the excitation angle θ_{C1_prop} is about 0°, the duty ratio is about 0.425. In the first modified example and the second modified example as well, the resonant frequencies or the anti-resonant frequencies are approximately coincident with each other in all of the excitation sections in the first curved region. In the first example embodiment, the first modified example, and the second modified example, a relationship between the absolute value of the excitation angle |θ_{C2_prop}| and the duty ratio in the second curved region is also the same as or similar to the relationship illustrated in FIG. 11. Therefore, the resonant frequencies or the anti-resonant frequencies are also approximately coincident with each other in all of the excitation sections in the second curved region.

The first modified example and the second modified example are configured similarly to the first example embodiment in any points other than the duty ratio. Therefore, the Q factor can be increased.

A relationship between the duty ratio and the frequency of each mode differs, depending on the reverse-velocity surface of the piezoelectric substrate. Therefore, depending on the configuration of the piezoelectric substrate or the configuration on the piezoelectric substrate, when the duty ratio is larger as the absolute values of the excitation angles |θ_{C1_prop}| and |θ_{C2_prop}| are larger, the resonant frequencies or the anti-resonant frequencies may approximately coincide with each other in all of the excitation sections. An example of this can be an acoustic wave device in which an IDT electrode provided on a substrate including only the rotated Y-cut-4° X-propagation LiNbO₃ is embedded in a thick SiO₂ film, or the like. Alternatively, in the excitation section through which the reference line N1 passes and in which the excitation angle θ_{C1_prop} is about 0°, the duty ratio is not necessarily maximum or minimum. Similarly, in the excitation section through which the reference line N2 passes and in which the excitation angle θ_{C2_prop} is about 0°, the duty ratio is not necessarily maximum or minimum.

In the first example embodiment, by varying the duty ratio according to the angle θch, the excitation angle θ_{C1_prop}, the angle θ_{C2}, or the excitation angle θ_{C2_prop} in each of the curved region, the resonant frequencies or the anti-resonant frequencies in all of the excitation sections are made approximately coincident with each other. In example embodiments of the present invention, setting of parameters such as the duty ratio are not particularly limited. However, for example, it is preferable that at least one of the duty ratio, the electrode finger pitch, as well as thicknesses of the plurality of first electrode fingers 16 and the plurality of second electrode fingers 17 vary depending on the angle θ_{C1} or the excitation angle θ_{C1_prop}, or the angle θ_{C2} or the excitation angle θ_{C2_prop}. It is preferable that at least one of these parameters vary depending on the above angles or the above excitation angles, so that the resonant frequencies or the anti-resonant frequencies approximately coincide with each other in all the excitation sections in each of the curved regions. This makes it possible to improve the resonance characteristics more reliably.

Alternatively, if a thickness of the intermediate layer in the piezoelectric substrate 2 or the like affects the frequency, the parameter may be varied in each of the curved regions, depending on the above angle or the above excitation angle. If a dielectric film is provided so as to cover the IDT electrode 8 on the piezoelectric substrate 2, a thickness of the dielectric film may be varied in each of the curved regions, depending on the angles or the excitation angles. A plurality of parameters of the parameters for the above IDT electrode 8 or parameters other than the IDT electrode 8 may be varied in each of the curved regions, depending on the above angle or the above excitation angle. In these cases as well, the resonant frequencies or the anti-resonant frequencies can be made coincident with each other in all the excitation sections.

The parameters of each of the reflectors, such as reflector electrode finger pitch or the duty ratio, may be different from the parameters of the electrode fingers of the IDT electrode 8 in the excitation sections. The reflector electrode finger pitch is a center-to-center distance between adjacent reflector electrode fingers. Each of the reflector electrode fingers may be configured in a pattern different from the shape of the electrode finger of the IDT electrode 8 in the excitation section.

Meanwhile, in the acoustic wave device 1, the shape of the plurality of electrode fingers in plan view includes a shape in which two arcs are connected. However, the shape is not limited thereto. In a third modified example of the first example embodiment illustrated in FIG. 12, in the IDT electrode 8A, the shape of the plurality of electrode fingers in plan view includes a shape in which two elliptical arcs are connected.

In this modified example as well, the intersecting region D of the IDT electrode 8A includes the first curved region W1 and the second curved region W2. In the first curved region W1, the shape of the plurality of electrode fingers in plan view is each a shape corresponding to each elliptical arc of a plurality of ellipses having the center of gravity at the same or substantially the same position. Then, a midpoint between a focus A1 and a focus B1 is the fixed point C1. In other words, the fixed point C1 is the center of gravity of the focus A1 and the focus B1. It can also be said that the center of gravity of the focus A1 and the focus B1 is the center of gravity of an ellipse having the focus A1 and the focus B1. The same applies to the second curved region W2. Then, a midpoint between a focus A2 and a focus B2 is the fixed point C2. In other words, the fixed point C2 is the center of gravity of the focus A2 and the focus B2. The ellipse coefficients x2/α1 of the shape of the plurality of electrode fingers in plan view, α12/α11 and α22/α21, are other than 1.

In this modified example as well, similarly to the first example embodiment, the plurality of first electrode patterns 18 and the plurality of second electrode patterns 19 are provided. This makes it possible to increase the Q factor.

The configurations of the IDT electrodes in the first example embodiment and the respective modified examples thereof are examples. In example embodiments of the present invention, for example, the shape of the IDT electrode may be a shape in which three or more fixed points are defined. Each of the electrode fingers may include a plurality of inflection points. In the intersecting region, the shape of each of the electrode fingers in plan view may have a linear shape as well as the curved shape.

In example embodiments of the present invention, the reference lines do not necessarily have to pass through the above fixed points. The reference lines can be defined individually in a local region of a curved line in the shape of each of the electrode fingers in plan view. In this case, the reference lines include origins other than the above fixed points. However, in an acoustic wave device according to an example embodiment of the present invention, it is preferable that directions in which a plurality of the reference lines extend are parallel or substantially parallel even when the plurality of reference lines having mutually different origins is defined.

In the first example embodiment, a width of each of the electrode fingers is changing continuously. However, the width of each of the electrode fingers may change discontinuously. In this case, for example, at a connection portion where each of the electrode fingers may have a configuration corresponding to a configuration in which a plurality of portions is connected and where different portions are connected with each other, widths of the connected portions may be different from each other.

For the design parameters of the acoustic wave device 1 according to the comparisons illustrated in FIGS. 7 and 8, examples of materials of each layer of the piezoelectric substrate 2 or the IDT electrode 8 in the acoustic wave device 1 are illustrated. However, the materials are not limited to the materials described above. A combination of each layer of the piezoelectric substrate 2 or the material of IDT electrode 8 may be a combination of appropriate materials by which acoustic waves are excited.

Specifically, as materials of the piezoelectric body layer 6 as illustrated in FIG. 2, for example, lithium tantalate, lithium niobate, zinc oxide, aluminum nitride, quartz crystals, or PZT (lead zirconate titanate), or the like can be used. It is preferable, for example, that lithium tantalate or lithium niobate is used as the material of the piezoelectric body layer 6.

As materials of the IDT electrode 8, for example, one or more metals of Ti, Mo, Ru, W, Al, Pt, Ir, Cu, Cr, or Sc may be used. The material the same as or similar to the IDT electrode 8 can be used in each of the reflectors. The IDT electrode 8 and each of the reflectors may include a single-layer metal film or a laminated metal film.

As materials of the intermediate layer 5 of the first example embodiment, for example, a dielectric such as silicon oxide, silicon nitride, silicon oxynitride, or tantalum oxide can be used.

As materials of the supporting substrate 4, for example, a piezoelectric body such as aluminum nitride, lithium tantalate, lithium niobate, quartz crystal, or the like, ceramics such as alumina, sapphire, magnesia, silicon nitride, silicon carbide, zirconia, cordierite, mullite, steatite, forsterite, or the like, a dielectric such as diamond or glass, or the like, a semiconductor such as silicon, gallium nitride, gallium arsenic, or the like, or a resin, or a material main component of which are the materials described above can be used. It is preferable that, for example, high-resistance silicon is used for the supporting substrate 4. Preferably, the volume resistivity of the material of the supporting substrate 4 is, for example, about 1000 Ω·cm or more. In this specification, main components refer to components that account for about 50 weight % or more. The materials of the above main components may be in any of a single crystal, polycrystal, or amorphous state, or may be a mixture of these.

In an example embodiment of the present invention, a configuration may be provided such that a piston mode can be used. In the following, an example of the configuration in which the piston mode is available is illustrated in a second example embodiment of the present invention. For the configuration in which the piston mode is used, a portion on any straight line passing through a fixed point in a region located in the central region of each of the curved regions, which is described below, is defined as an excitation section.

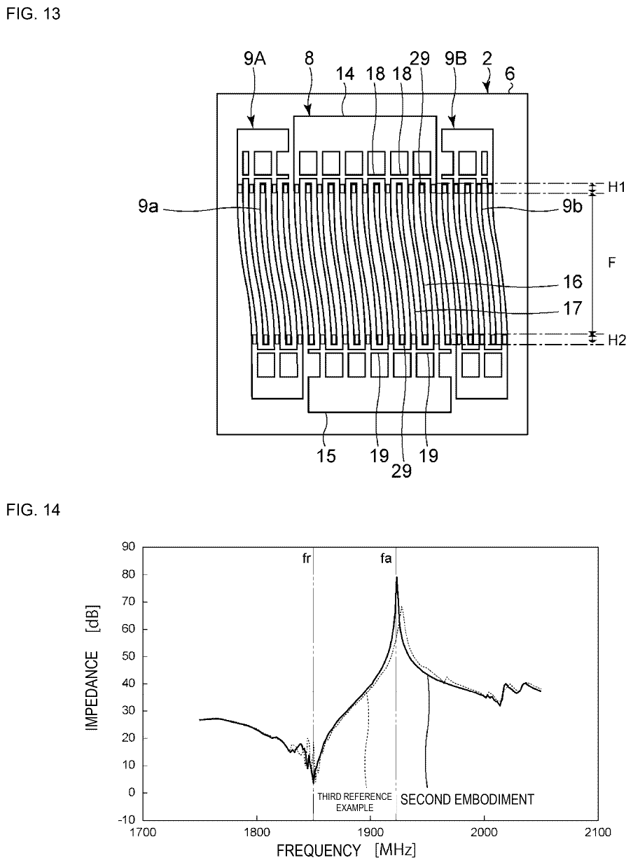

FIG. 13 is a schematic plan view of an acoustic wave device according to the second example embodiment.

This example embodiment differs from the first example embodiment in that a mass addition film is provided on each of the electrode fingers and on each of the reflector electrode fingers. The acoustic wave device of the present example embodiment has a configuration the same as or similar to that of the acoustic wave device 1 of the first example embodiment, except for the above point.

The intersecting region D of the IDT electrode 8 includes a central region F and a pair of edge regions. Specifically, the pair of edge regions include a first edge region H1 and a second edge region H2. The first edge region H1 includes the first envelope E1 as an edge portion. The second edge region H2 includes the second envelope E2 as an edge portion. The first edge region H1 and the second edge region H2 are opposed to each other with the central region F interposed therebetween. Here, it is the regions of the IDT electrode 8 that are defined, and the configuration of the IDT electrode 8 in the present example embodiment is the same or substantially the same as that of the IDT electrode 8 in the first example embodiment.

In the present example embodiment, the shape of each of the electrode fingers in each of the edge regions when viewed in plan view may be curved or linear.

A plurality of mass addition films 29 are provided in the first edge region H1. Specifically, the mass addition film 29 is provided on each of the first electrode fingers 16 and on each of the second electrode fingers 17. As a result, a low acoustic velocity region is provided in the first edge region H1. A low acoustic velocity region is a region where the acoustic velocity is lower than that in the central region F.

Similarly, a plurality of the mass addition films 29 are provided in the second edge region H2. This also provides a low acoustic velocity region in the second edge region H2. In the present example embodiment, each of the mass addition films 29 is provided only on one of the electrode fingers. In this case, as a material of the mass addition film 29, an appropriate metal or dielectric can be used.

The mass addition film 29 is also provided on each of the reflector electrode fingers 9a of the reflector 9A in each region where each of the edge regions is extended in a direction in which the first busbar 14 extends. Similarly, in that region, the mass addition film 29 is also provided on each of the reflector electrode fingers 9b of the reflector 9B. However, the mass addition film 29 does not have to be provided on the reflector electrode fingers 9a of the reflector 9A or on the reflector electrode fingers 9b of the reflector 9B.

In the present example embodiment, the central region F and the pair of low acoustic velocity regions are disposed in this order, from an inner side portion to an outer side portion in a direction in which the first busbar 14 and the second busbar 15 are opposed. This establishes the piston mode. This makes it possible to effectively confine energy in the main mode to the central side of the intersecting region D, to improve main mode characteristics, and to reduce or prevent the transverse mode.

In addition, the shape of each of the electrode fingers of the IDT electrode 8 in plan view includes a curved shape the same as or similarly to that of the first example embodiment. Therefore, the spurious waves outside of the pass band can be dispersed. Furthermore, the plurality of first electrode patterns 18 and the plurality of second electrode patterns 19 are provided in the IDT electrode 8. This makes it possible to reduce or prevent the leakage of acoustic wave energy and increase the Q factor. In the following, the advantageous effects capable of increasing the Q factor of the present example embodiment are described by comparison of the present example embodiment with the third reference example.

The third reference example differs from the second example embodiment in that the configuration of the IDT electrode is the same as or similar to that of the IDT electrode in the acoustic wave device 301 of the second reference example illustrated in FIG. 6. In the third reference example, the mass addition film is provided on each of the electrode fingers in each of the edge regions, as in the second example embodiment. According to the comparison, the design parameters of the acoustic wave device of the second example embodiment are the same as or similar to the design parameters of the acoustic wave device 1 of the first example embodiment according to the comparison in FIGS. 7 and 8, except for the mass addition film. According to the comparison, the design parameters of the acoustic wave device of the third reference example are the same as or similar to the design parameters of the acoustic wave device 301 of the second reference example according to the comparison in FIGS. 7 and 8, except for the mass addition film. The impedance frequency characteristics as well as the relationship between the frequency and the Q factor were determined for each of the acoustic wave devices of the second example embodiment and the third reference example.

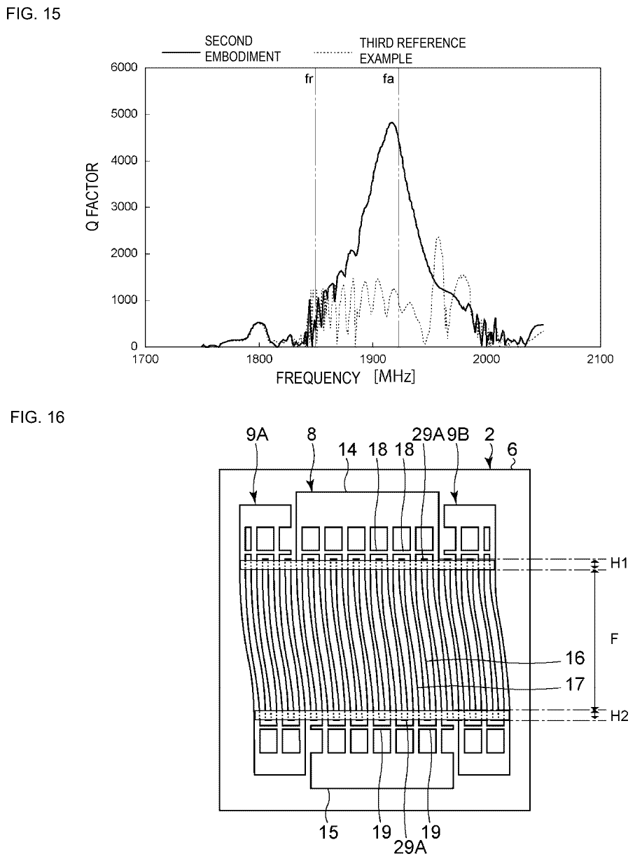

FIG. 14 is a diagram illustrating the impedance frequency characteristics in the second example embodiment and the third reference example. FIG. 15 is a diagram illustrating the relationship between the frequency and the Q factor in the second example embodiment and the third reference example.

As illustrated in FIG. 14, it can be seen the impedance ratio is larger in the second example embodiment than in the third reference example. Furthermore, it can be seen that the transverse mode between the resonant frequencies and the anti-resonant frequencies can be reduced or prevent in the second example embodiment.

As illustrated in FIG. 15, it can be seen that the Q factor is higher in the second example embodiment than in the third reference example. Specifically, in the second example embodiment, the Q factor around the anti-resonant frequencies, in particular, is higher. As a result, the impedance at the anti-resonant frequencies is higher in the second example embodiment. Consequently, the impedance ratio can be successfully made large in the second example embodiment.

It is sufficient if a low acoustic velocity region is provided in at least one of the first edge region H1 and the second edge region H2. However, it is preferable that the low acoustic velocity region is provided in both the first edge region H1 and the second edge region H2. This can establish the piston mode more reliably.

The mass addition film 29 may be laminated with at least one of the plurality of electrode fingers in at least one of the first edge region H1 and the second edge region H2. However, it is preferable that the plurality of electrode fingers are laminated with the mass addition film 29 in at least one of the first edge region H1 and the second edge region H2, and it is more preferable that all of the electrode fingers are laminated with the mass addition film 29. It is more preferable that the plurality of electrode fingers are laminated with the mass addition films 29 in both of the first edge region H1 and the second edge region H2. This can establish the piston mode more reliably. It is further preferable that all of the electrode fingers are laminated with the mass addition film 29 in both of the edge regions. In this case, the low acoustic velocity region is provided in the entirety or substantially the entirety of both of the edge regions. This can further establish the piston mode reliably.

In the second example embodiment, in portions where the electrode finger and the mass addition film 29 are laminated, the piezoelectric substrate 2, the electrode finger, and the mass addition film 29 are laminated in this order. However, in the portion where the electrode finger and the mass addition film 29 are laminated, the lamination may be in the order of the piezoelectric substrate 2, the mass addition film 29, and the electrode finger. That is, the mass addition film 29 may be provided between the piezoelectric substrate 2 and the electrode finger. It is sufficient if the mass addition film 29 overlaps with the electrode finger when viewed in plan view.

In the following, first to fourth modified examples of the second example embodiment are described. In the first to fourth modified examples as well, the main mode characteristics can be improved, the transverse mode and the spurious waves outside of the pass band can be reduced or prevented, and the Q factor can be increased, as in the second example embodiment.

In the first modified example illustrated in FIG. 16, the IDT electrode 8 is configured the same as or similar to the second example embodiment. One mass addition film 29A is provided in each of the first edge region H1 and the second edge region H2. As a result, the low acoustic velocity region is provided in the first edge region H1 and the second edge region H2.

More specifically, each mass addition film 29A has a band shape. One mass addition film 29A of a pair of the mass addition films 29A is provided over the plurality of electrode fingers in the first edge region H1. Similarly, another mass addition film 29A is provided over the plurality of electrode fingers in the second edge region H2. Each mass addition film 29A is also provided in a portion between the electrode fingers on the piezoelectric body layer 6. An appropriate dielectric can be used as a material of the mass addition film 29A.

It is sufficient if the mass addition film 29A is laminated with at least one of the plurality of electrode fingers in at least one of the first edge region H1 and the second edge region H2. In this case, the mass addition film 29A may be provided over a portion where the electrode fingers are provided and the portion between the electrode fingers. However, it is preferable that the plurality of electrode fingers are laminated with the mass addition films 29A in at least one of the first edge region H1 and the second edge region H2, and it is more preferable that all of the electrode fingers are laminated with the mass addition films 29A. Then, it is more preferable that the plurality of electrode fingers are laminated with the mass addition films 29A in both the first edge region H1 and the second edge region H2, and it is further preferable that all of the electrode fingers are laminated with the mass addition films 29A. This can establish the piston mode more reliably.

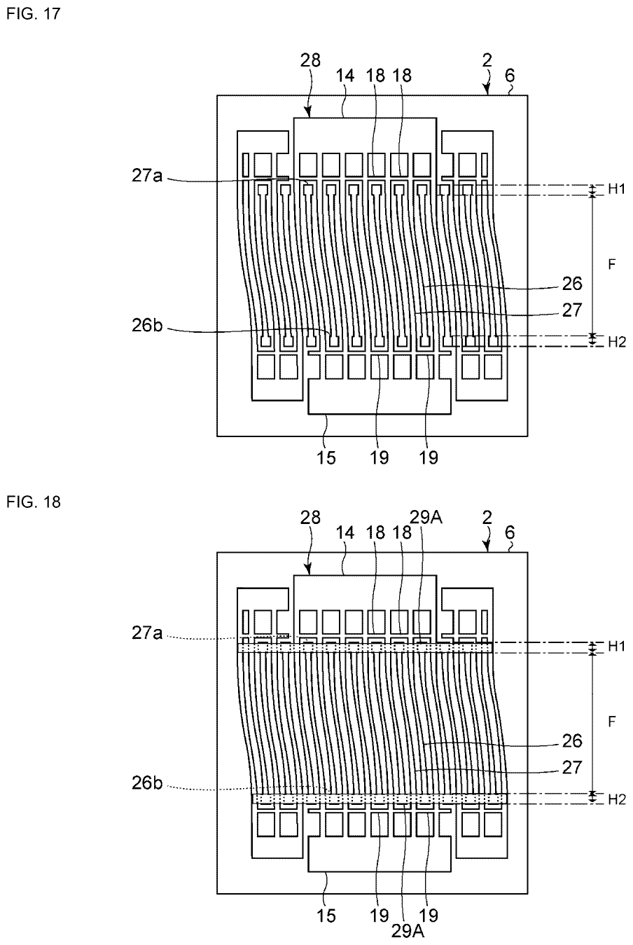

In the second modified example illustrated in FIG. 17, each of the electrode fingers of an IDT electrode 28 includes a wide portion in the first edge region H1 and the second edge region H2. A width of each of the electrode fingers in the wide portion is wider than that of the electrode finger in the central region F.

More specifically, a second electrode finger 27 includes a wide portion 27a in the first edge region H1. In contrast, a first electrode finger 26 includes a wide portion 26b in the second edge region H2. As a result, the acoustic velocity in the first edge region H1 and the second edge region H2 are lower than that in the central region F. Therefore, the low acoustic velocity region is provided in the first edge region H1 and the second edge region H2.

It is sufficient if at least one of the electrode fingers includes a wide portion in at least one of the first edge region H1 and the second edge region H2. However, it is preferable that the plurality of electrode fingers each include a wide portion in at least one of the first edge region H1 and the second edge region H2, and it is more preferable that all of the electrode fingers each include a wide portion. Then, it is more preferable that the plurality of electrode fingers each include a wide portion in both the first edge region H1 and the second edge region H2, and it is further preferable that all of the electrode fingers include a wide portion. This can establish the piston mode more reliably.

In this modified example, the width of each of the electrode fingers is wide over the entire or substantially the entire edge regions. Each wide portion has a quadrangular shape in plan view. However, the width of each of the electrode fingers may be wide in at least a portion of each of the edge regions. The shape of the wide portion in plan view is not limited to a quadrangle.

In the third modified example illustrated in FIG. 18, the IDT electrode 28 is configured the same as or similar to the second modified example. One mass addition film 29A is provided in each of the first edge region H1 and the second edge region H2 as in the first modified example. As a result, the low acoustic velocity region is provided in the first edge region H1 and the second edge region H2. That is, the low acoustic velocity region is provided, due to both of the configuration in which each of the electrode fingers includes a wide portion and the configuration in which the mass addition film 29A is provided. This easily increases a difference in acoustic velocities in the central region F and each of the edge regions. Therefore, it is possible to effectively reduce or prevent the transverse mode more reliably.

In the first modified example and this modified example, in the portion where the electrode finger and the mass addition film 29A are laminated, the piezoelectric substrate 2, the electrode finger, and the mass addition film 29A are laminated in this order. However, in the portion where the electrode finger and the mass addition film 29A are laminated, the lamination may be in the order of the piezoelectric substrate 2, the mass addition film 29A, and the electrode finger. That is, the mass addition film 29A may be provided between the piezoelectric substrate 2 and the electrode finger.

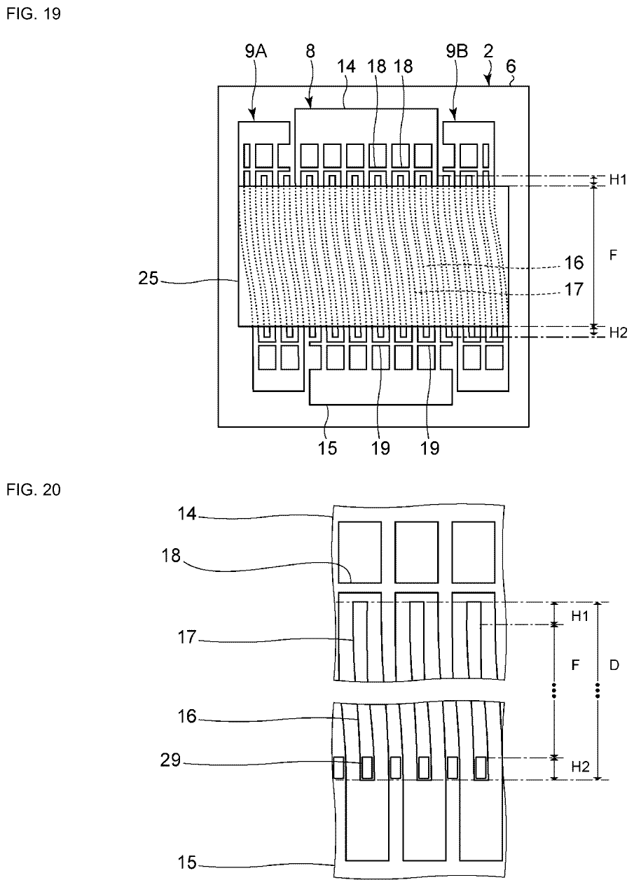

In a fourth modified example illustrated in FIG. 19, a high acoustic velocity film 25 is provided in the central region F in the IDT electrode 8 the same as or similar to the second example embodiment. As a result, the acoustic velocity in the central region F is high. Therefore, the acoustic velocity in the first edge region H1 and the second edge region H2 is lower than that in the central region F. That is, the low acoustic velocity region is provided in both of the first edge region H1 and the second edge region H2.

The high acoustic velocity film 25 may also be provided in the central region F in the configurations of the first to third modified examples. Preferably, for example, an insulating material such as silicon nitride, silicon carbide, aluminum nitride, aluminum oxide, or a diamond thin film is used as a material of the high acoustic velocity film 25 laminated with the IDT electrode 8.

In this modified example, in a portion where the electrode finger and the high acoustic velocity film 25 are laminated, the piezoelectric substrate 2, the electrode finger, and the high acoustic velocity film 25 are laminated in this order. However, in the portion where the electrode finger and the high acoustic velocity film 25 are laminated, lamination may be in the order of the piezoelectric substrate 2, the high acoustic velocity film 25, and the electrode finger. That is, the high acoustic velocity film 25 may be provided between the piezoelectric substrate 2 and the electrode finger.

Referring back to FIG. 13, in the second example embodiment, the first electrode pattern 18 is provided between all of the first electrode fingers 16. Similarly, the second electrode pattern 19 is provided between all of the second electrode fingers 17. In example embodiments of the present invention, the first electrode patterns 18 do not necessarily have to be provided between all of the first electrode fingers 16. The second electrode patterns 19 do not necessarily have to be provided between all of the second electrode fingers 17.

In the following, fifth to seventh modified examples of the second example embodiment are described. In the fifth to seventh modified examples as well, the main mode characteristics can be improved, the transverse mode and the spurious waves outside of the pass band can be reduced or prevented, and the Q factor can be increased. However, as in the second example embodiment, it is preferable that the first electrode patterns 18 are provided between all of the first electrode fingers 16, and the second electrode patterns 19 are provided between all of the second electrode fingers 17. Then, it is preferable that the low acoustic velocity region is provided in both the first edge region H1 and the second edge region H2.

In the fifth modified example illustrated in FIG. 20, the first electrode pattern 18 is provided between all of the first electrode fingers 16. On the other hand, the second electrode pattern 19 is not provided. The low acoustic velocity region is provided only in at least a portion of the second edge region H2. More specifically, in this modified example, the low acoustic velocity region is provided in the entire or substantially the entire second edge region H2.

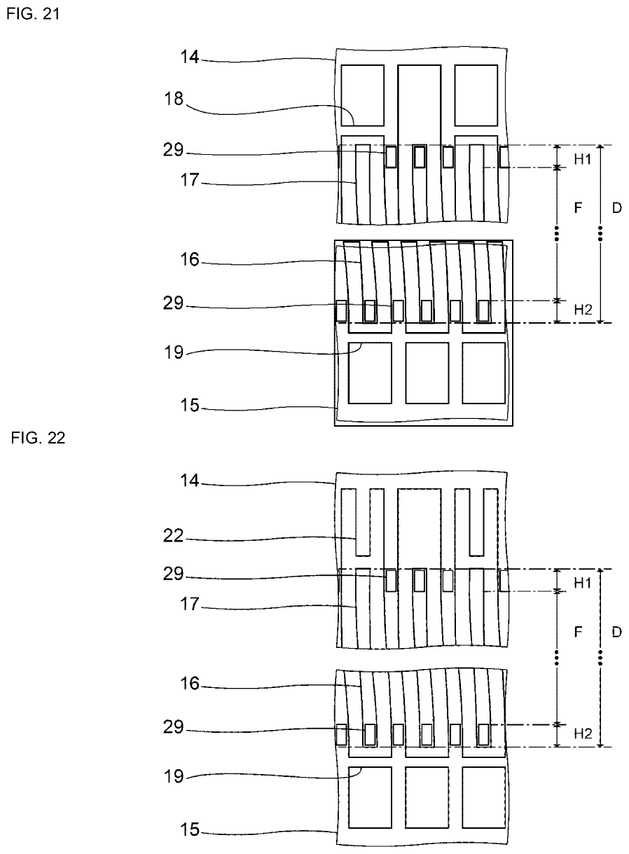

In the sixth modified example illustrated in FIG. 21, some second electrode fingers 17 of all the second electrode fingers 17 face the first electrode patterns 18. The low acoustic velocity region is provided in a portion of the first edge region H1. At least one of the second electrode fingers 17 is located in a portion of the first edge region H1 where no low acoustic velocity region is provided. The tip portion of the at least one of the second electrode fingers 17 faces the first electrode pattern 18.

More specifically, in this modified example, the first electrode pattern 18 is provided between every other first electrode finger 16 arranged in the direction in which the first busbar 14 extends. Therefore, every other second electrode finger 17 faces the first electrode pattern 18. Then, in the first edge region H1, the mass addition film 29 is laminated on every other second electrode finger 17. The second electrode finger 17 on which the mass addition film 29 is laminated does not face the first electrode pattern 18. However, an arrangement in which the first electrode patterns 18 are provided and an arrangement in which the mass addition films 29 are provided in the first edge region H1 are not limited to the above.

In this modified example, the second electrode pattern 19 is provided between all of the second electrode fingers 17 and the low acoustic velocity region is provided in the entire or substantially the entire second edge regions H2.

In the seventh modified example illustrated in FIG. 22, the first electrode pattern 18 is not provided. The low acoustic velocity region is provided in a portion of the first edge region H1. At least one of the second electrode fingers 17 is located in the portion of the first edge region H1 where no low acoustic velocity region is provided. Then, the first offset electrode 22 is provided so as to face the at least one of the second electrode fingers 17.

The first offset electrode 22 is configured the same as or similar to the first offset electrode 22 in the first reference example illustrated in FIG. 5. That is, the base end portion, which is one end of the first offset electrode 22, is connected to the first busbar 14. The tip portion of the first offset electrode 22 is opposed to the tip portion of the second electrode finger 17 with a gap therebetween.

In this modified example, as in the sixth modified example, the mass addition film 29 is laminated on every other second electrode finger 17 in the first edge region H1. The second electrode finger 17 on which the mass addition film 29 is laminated does not face the first offset electrode 22. The second electrode finger 17 on which the mass addition film 29 is not laminated faces the first offset electrode 22.

In this modified example, the second electrode pattern 19 is provided between all of the second electrode fingers 17, and the low acoustic velocity region is provided in the entire or substantially the entire second edge regions H2.

In the first example embodiment, the second example embodiment, and the respective modified examples, an example is illustrated in which each of the electrode patterns has a rectangular shape extending parallel or substantially parallel to the busbar, and is connected to both of adjacent electrode fingers.

However, the configuration of the electrode patterns in example embodiments of the present invention is not limited to the above. A third example embodiment of the present invention illustrates an example of another configuration of the electrode patterns.

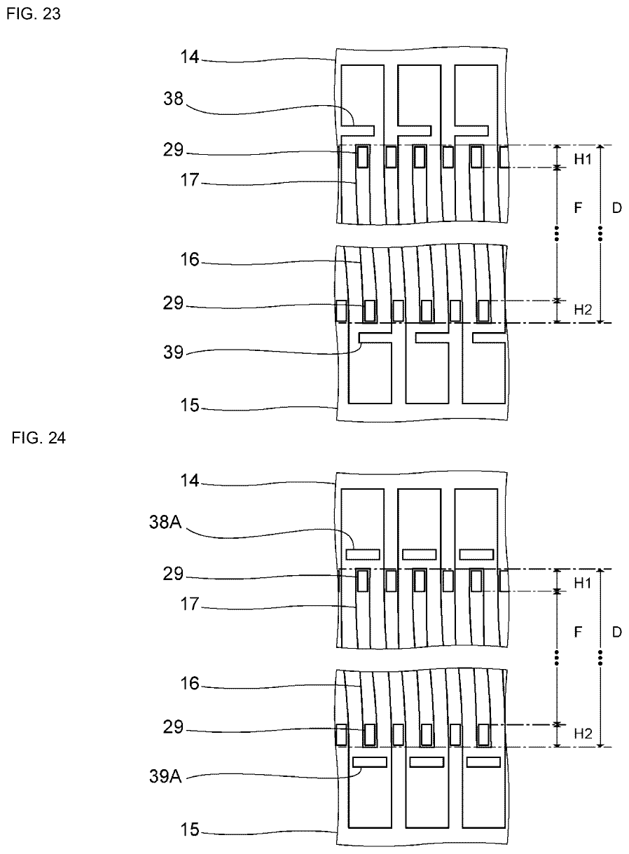

FIG. 23 is a schematic plan view illustrating the vicinity of the first electrode pattern and that of the second electrode pattern of the IDT electrode in the third example embodiment.

The present example embodiment differs from the second example embodiment in a configuration of connection with the electrode fingers in a first electrode pattern 38 and a second electrode pattern 39. Except for the above point, an acoustic wave device of the present example embodiment has a similar configuration to the acoustic wave device of the second example embodiment.

In plan view, the first electrode pattern 38 has a rectangular shape extending parallel or substantially parallel to the first busbar 14, and is connected to only one of the adjacent first electrode fingers 16. Similarly, in plan view, the second electrode pattern 39 has a rectangular shape extending parallel or substantially parallel to the second busbar 15, and is connected to only one of the adjacent second electrode fingers 17. In the present example embodiment as well, as in the second example embodiment, the main mode characteristics can be improved, the transverse mode and the spurious waves outside of the pass band can be reduced or prevented, and the Q factor can be increased.

It is sufficient if at least one of the first electrode patterns has the above-described configuration. The plurality of first electrode patterns may include, for example, the first electrode patterns of the first example embodiment and the first electrode pattern of the present example embodiment. The same also applies to the second electrode patterns.

In the following, first to fourth modified examples of the third example embodiment, which differ from the third example embodiment only in the configurations of the first electrode patterns and the second electrode patterns, are described. In the first to fourth modified examples as well, as in the third example embodiment, the main mode characteristics can be improved, the transverse mode and the spurious waves outside of the pass band can be reduced or prevented, and the Q factor can be increased.

In the first modified example illustrated in FIG. 24, in plan view, a first electrode pattern 38A has a rectangular shape extending parallel or substantially parallel to the first busbar 14, and is not connected to any of the adjacent first electrode fingers 16. Similarly, a second electrode pattern 39A has a rectangular shape extending parallel or substantially parallel to the second busbar 15, and is not connected to any of the adjacent second electrode fingers 17.

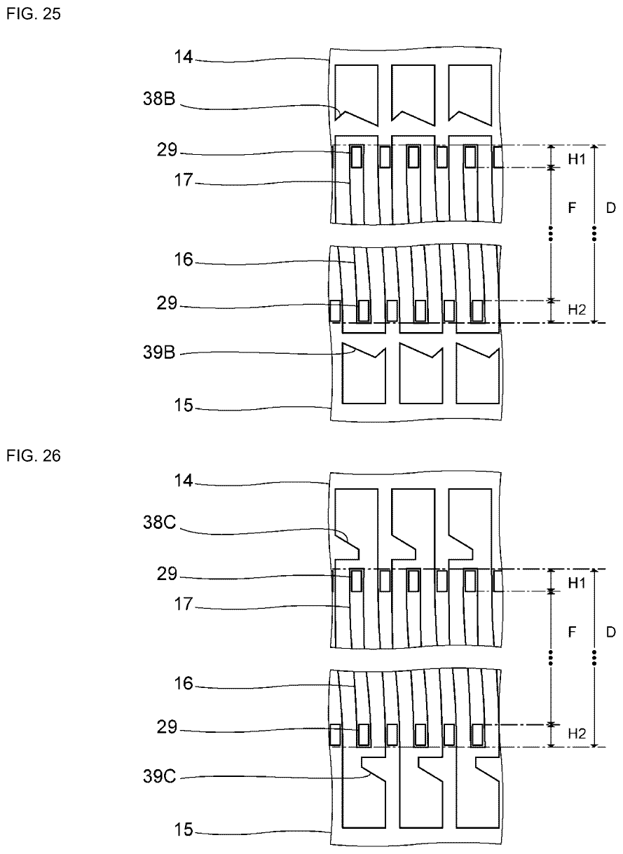

In the second modified example illustrated in FIG. 25, in plan view, a first electrode pattern 38B has a shape including a side not extending parallel or substantially parallel to the first busbar 14, and is connected to both of the adjacent first electrode fingers 16. Specifically, the side of the first electrode pattern 38B facing the first busbar 14 in the first electrode pattern 38B does not extend parallel or substantially parallel to the first busbar 14. In contrast, a side facing the second electrode finger 17 extends parallel or substantially parallel to the first busbar 14. In this modified example, the first electrode pattern 38B has a pentagonal shape in plan view. Similarly, a second electrode pattern 39B also has a pentagonal shape in plan view. In this manner, the shapes of the first electrode pattern and the second electrode pattern in plan view in the present invention may be polygonal other than a quadrangle.

In the third modified example illustrated in FIG. 26, a first electrode pattern 38C has a shape including a side not extending parallel or substantially parallel to the first busbar 14 in plan view, and is connected to only one of the adjacent first electrode fingers 16. Specifically, the side of the first electrode pattern 38C facing the first busbar 14 does not extend parallel or substantially parallel to the first busbar 14. In contrast, a side facing the second electrode finger 17 extends parallel or substantially parallel to the first busbar 14. Similarly, a second electrode pattern 39C also has a shape including a side not extending parallel or substantially parallel to the second busbar 15 in plan view, and is connected to only one of the adjacent second electrode fingers 17.

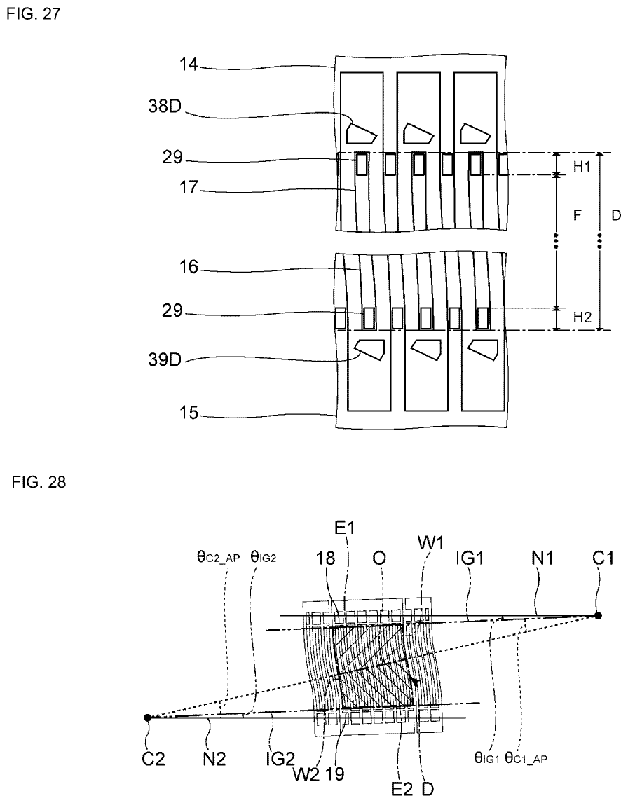

In the fourth modified example illustrated in FIG. 27, a first electrode pattern 38D has a shape including a side not extending parallel or substantially parallel to the first busbar 14 in plan view, and is not connected to any of the adjacent first electrode fingers 16. Specifically, the side of the first electrode pattern 38D facing the first busbar 14 does not extend parallel or substantially parallel to the first busbar 14. In contrast, the side facing the second electrode finger 17 extends parallel or substantially parallel to the first busbar 14. The first electrode pattern 38D has a pentagonal shape in plan view. Similarly, a second electrode pattern 39D has also the pentagonal shape in plan view, and is not connected to any of the adjacent second electrode fingers 17.

At least one of the plurality of first electrode patterns may have any of the configurations of the respective modified examples. The plurality of first electrode patterns may include first electrode patterns with mutually different configurations. This also applies to the plurality of second electrode patterns.

FIG. 28 is a schematic plan view for describing a configuration of an IDT electrode in a fourth example embodiment of the present invention.

The present example embodiment differs from the first example embodiment in that the reference line N1 does not include the first envelope E1 and the extended line of the first envelope E1. The reference line N1 is the straight line that extends parallel or substantially parallel to the propagation axis of the piezoelectric body layer and passes through the fixed point C1. This example embodiment also differs from the first example embodiment in that the reference line N2 does not include the second envelope E2 and the extended line of the second envelope E2. The reference line N2 is the straight line that extends parallel or substantially parallel to the propagation axis of the piezoelectric body layer and passes through the fixed point C2. Furthermore, the present example embodiment also differs from the first example embodiment in that the first envelope E1 and the second envelope E2 are inclined with respect to the propagation axis. Except for the above points, an acoustic wave device of the present example embodiment has a similar configuration to that of the acoustic wave device 1 of the first example embodiment.

A straight line including the first envelope E1 and the extended line of the first envelope E1 is defined as a straight line IG1. The fixed point C1 is located on the straight line IG1. An angle between the straight line IG1 and the reference line N1 is defined as an envelope inclination angle θ_{IG1}. On the other hand, a straight line including the second envelope E2 and the extended line of the second envelope E2 is defined as a straight line IG2. The fixed point C2 is located on the straight line IG2. An angle between the straight line IG2 and the reference line N2 is defined as an envelope inclination angle θI_{G2}. Absolute values of the envelope inclination angle θ_{IG1} and the envelope inclination angle θ_{IG2} are about 90° or less. In this specification, positive directions of both the envelope inclination angle θ_{IG1} and the envelope inclination angle θI_{G2} are counterclockwise directions when viewed in plan view.

As described above, in the present example embodiment, the reference line N1 and the reference line N2 extend parallel or substantially parallel to the propagation axis. Therefore, the envelope inclination angle θrGi is an angle at which the first envelope E1 is inclined with respect to the propagation axis. The envelope inclination angle θ_{IG2} is an angle at which the second envelope E2 is inclined with respect to the propagation axis. In the IDT electrode of the present example embodiment, the envelope inclination angle θ_{IG1} and the envelope inclination angle θI_{G2} are the same or substantially the same. More specifically, for example, θ_{IG1}=θ_{IG2}=about 2°. However, each of the envelope inclination angles is not limited to the above.

The IDT electrode of the present example embodiment includes the plurality of first electrode patterns 18 and the plurality of second electrode patterns 19 as in the first example embodiment. Therefore, the leakage of acoustic wave energy can be reduced or prevented and the Q factor can be increased.

In the present example embodiment as well, as in the first example embodiment, the angle θ_{c1}, the excitation angle θ_{c1_prop}, and the intersecting angle θ_{C1_AP} are defined with reference to the reference line N1. The angle θ_{c2}, the excitation angle θ_{c2_prop}, and the intersecting angle θ_{C2_AP} are defined with reference to the reference line N2. Then, in the present example embodiment, for example, θ_{C1_AP}=θ_{C2_AP}=about 10°.

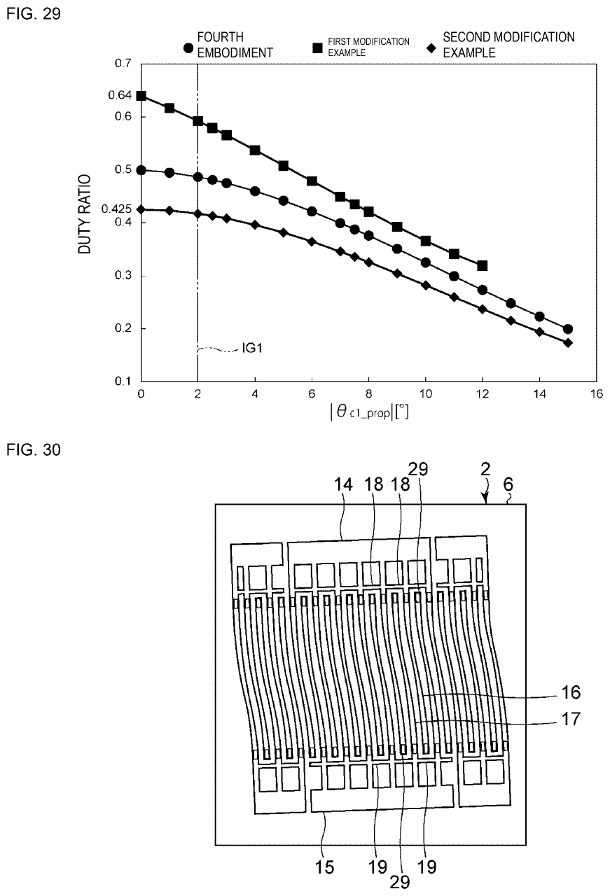

By varying the duty ratio in the IDT electrode according to the excitation angle θ_{C1_prop} or the excitation angle θ_{C2_prop} in each of the curved region, the resonant frequencies or the anti-resonant frequencies in all of the excitation sections are made approximately coincident with each other. FIG. 29 illustrates the relationship between the excitation angle θ_{C1_prop} and the duty ratio in the fourth example embodiment. Examples in which the maximum value of the duty ratio differs from the fourth example embodiment are also illustrated as a first modified example and a second modified example of the fourth example embodiment.

FIG. 29 is a diagram illustrating the relationship between the absolute value of the excitation angle |θ_{C1_prop}| and the duty ratio of the IDT electrode in the fourth example embodiment, the first modified example, and the second modified example. A two-dot chain line in FIG. 29 represents a position on the straight line IG1.

In the fourth example embodiment, the duty ratio is set to the maximum value when the excitation angle θ_{C1_prop} is about 0°. In the fourth example embodiment, for example, when the excitation angle θ_{C1_prop} is about 0°, the duty ratio is about 0.5. Then, the larger the absolute value of the excitation angle |θ_{C1_prop}|, the smaller the duty ratio. As a result, the resonant frequencies or the anti-resonant frequencies are approximately coincident with each other in all of the excitation sections in the first curved region.

In the first modified example and the second modified example as well, the larger the absolute value of the excitation angle |θ_{C1_prop}|, the smaller the duty ratio. In the first modified example, when the excitation angle θ_{C1_prop} is about 0°, the duty ratio is about 0.64, for example. In the second modified example, when the excitation angle θ_{C1_prop} is about 0°, the duty ratio is about 0.425, for example. In the first modified example and the second modified example as well, the resonant frequencies or the anti-resonant frequencies are approximately coincident with each other in all of the excitation sections in the first curved region. In the fourth example embodiment, the first modified example, and the second modified example, the relationship between the absolute value of the excitation angle |θ_{C2_prop}| and the duty ratio in the second curved region is also the same as or similar to the relationship illustrated in FIG. 29. Therefore, the resonant frequencies or the anti-resonant frequencies are also approximately coincident with each other in all of the excitation sections in the second curved region.

The first modified example and the second modified example are configured similarly to the fourth example embodiment, except for the duty ratio. Therefore, the Q factor can be increased.

Meanwhile, in the fourth example embodiment as well, the low acoustic velocity region may be provided as in the second example embodiment. For example, in the third modified example of the fourth example embodiment illustrated in FIG. 30, the mass addition film 29 is laminated on each of the electrode fingers of the IDT electrode as in the second example embodiment. That is, the mass addition film 29 is laminated on each of the electrode fingers in each of the edge regions. This can establish the piston mode. Then, in this modified example as well, the plurality of first electrode patterns 18 and second electrode patterns 19 are provided. These can improve the main mode characteristics, can reduce or prevent the transverse mode and the spurious waves outside of the pass band, and can increase the Q factor.

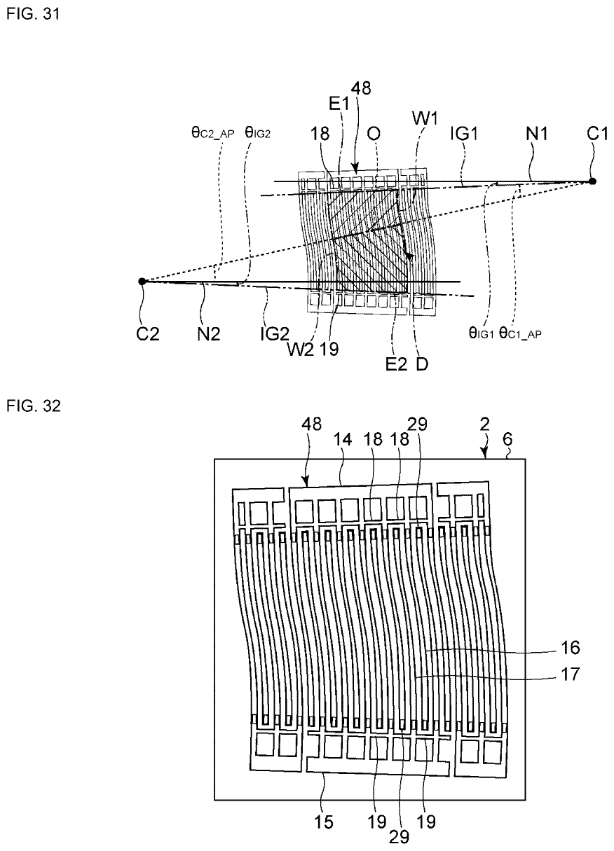

FIG. 31 is a schematic plan view for describing a configuration of an IDT electrode in a fifth example embodiment of the present invention.

The present example embodiment differs from the fourth example embodiment in the envelope inclination angle @I_{G2}. Specifically, in the fourth example embodiment, θ_{IG1}=θ_{IG2}=about 2°. In contrast, in the present example embodiment, θ_{IG1}=about 2° and θ_{IG2}=about −2°. Except for the above point, an acoustic wave device of the present example embodiment has a similar configuration to that of the acoustic wave device of the fourth example embodiment.

In the present example embodiment, θ_{IG1} ¥ θ_{IG2}. Furthermore, signs of the envelope inclination angle θ_{IG1} and the envelope inclination angle θ_{IG2} are opposite to each other. That is, the first envelope E1 and the second envelope E2 extend at an angle in opposite directions to each other with respect to the propagation axis.

An IDT electrode 48 includes the plurality of first electrode patterns 18 and the plurality of second electrode patterns 19, as in the fourth example embodiments. Therefore, the leakage of acoustic wave energy can be reduced or prevented and the Q factor can be increased.

In the present example embodiment, the signs of the envelope inclination angle θrGi and the envelope inclination angle @I_{G2} are opposite to each other, and the absolute values are the same or substantially the same. Therefore, the first envelope E1 and the second envelope E2 are line-symmetric with respect to a symmetric axis extending in a direction parallel or substantially parallel to the propagation axis. However, the signs of the envelope inclination angle θ_{IG1} and the envelope inclination angle θ_{IG2} may be opposite to each other and the absolute values may be different. The signs of the envelope inclination angle θ_{IG1} and the envelope inclination angle θ_{IG2} may be the same and the absolute values may be different. Alternatively, for example, the first envelope E1 may be inclined with respect to the propagation axis, and the second envelope E2 does not have to be inclined to the propagation axis.

Meanwhile, in the fifth example embodiment, the low acoustic velocity region may be provided, as in the second example embodiment. For example, in the modified example of the fifth example embodiment illustrated in FIG. 32, the mass addition film 29 is laminated on each of the electrode fingers of the IDT electrode 48, as in the second example embodiment. That is, the mass addition film 29 is laminated on each of the electrode fingers in each of the edge regions. This can establish the piston mode. Then, in this modified example as well, the IDT electrode 48 is configured the same as or similar to the fifth example embodiment, and the plurality of first electrode patterns 18 and second electrode patterns 19 are provided. These can improve the main mode characteristics, can reduce or prevent the transverse mode and the spurious waves outside of the pass band, and can increase the Q factor.

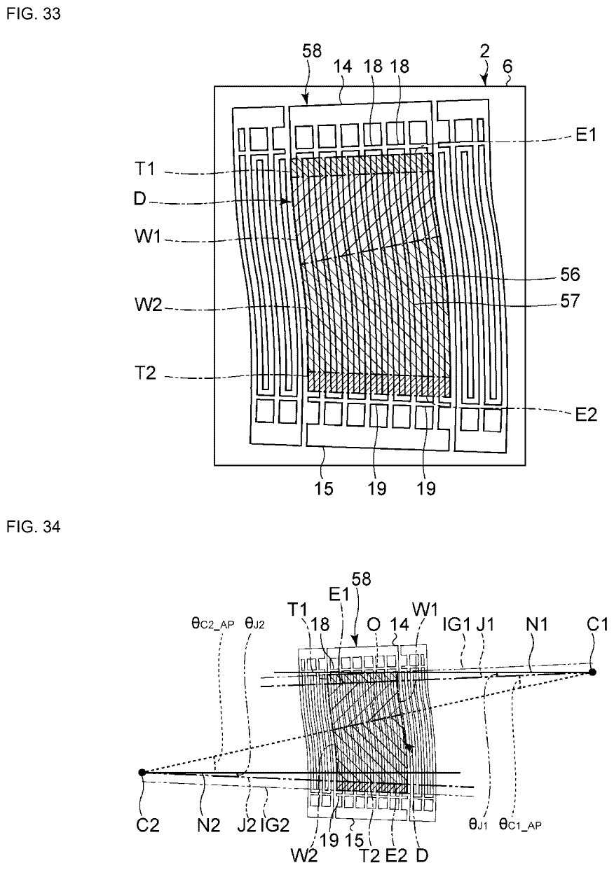

FIG. 33 is a schematic plan view of an acoustic wave device according to a sixth example embodiment of the present invention. FIG. 34 is a schematic plan view for describing a configuration of an IDT electrode in the sixth example embodiment.

As illustrated in FIG. 33, the present example embodiment differs from the fifth example embodiment in that the intersecting region D includes a first straight line region T1 and a second straight line region T2. As illustrated in FIG. 34, the present example embodiment also differs from the fifth example embodiment in that the straight line IG1 does not pass through the fixed point C1 and that the straight line I_{G2} does not pass through the fixed point C2. Except for the above points, an acoustic wave device of the present example embodiment has a similar configuration to the acoustic wave device of the fifth example embodiment.

In the intersecting region D, the first straight line region T1, the first curved region W1, the second curved region W2, and the second straight line region T2 are arranged in this order, from the first busbar 14 side toward the second busbar 15 side. The first straight line region T1 includes the first envelope E1. On the other hand, the second straight line region T2 includes the second envelope E2.

As illustrated in FIG. 33, in the first straight line region T1 and the second straight line region T2, shapes of first electrode fingers 56 and second electrode fingers 57 are linear in plan view.

As illustrated in FIG. 34, a straight line extending parallel or substantially parallel to the straight line IG1 and passing through the fixed point C1 is defined as a straight line J1. The straight line J1 includes an edge portion of the first curved region W1 on the first busbar 14 side and an extended line of the edge portion. An angle between the straight line J1 and the reference line N1 is defined as an edge portion inclination angle θ_{J1}. On the other hand, a straight line extending parallel or substantially parallel to the straight line IG2 and passing through the fixed point C2 is defined as a straight line J2. The straight line J2 includes an edge portion on the second busbar 15 side and an extended line of the edge portion in the second curved region W2. An angle between the straight line J2 and the reference line N2 is defined as an edge portion inclination angle θ_{J2}. Absolute values of the edge portion inclination angle θ_{J1} and the edge portion inclination angle θ_{J2} are about 90° or less. In this specification, positive directions of both of the edge portion inclination angle θ_{J1} and the edge portion inclination angle θ_{J2} are defined as counterclockwise directions when viewed in plan view.

In an IDT electrode 58, for example, θ_{J1}=about 2° and θ_{J2}=about −2°. In this manner, signs of the edge portion inclination angle θu and the edge portion inclination angle θ_{J2} are opposite to each other, and the absolute values are the same or substantially the same. Therefore, the edge portion of the first curved region W1 on the first busbar 14 side and the edge portion of the second curved region W2 on the second busbar 15 side are line-symmetric with respect to the symmetric axis extending in the direction parallel or substantially parallel to the propagation axis.

However, the signs of the edge portion inclination angle θ_{J1} and the edge portion inclination angle θ_{J2} are opposite to each other, and the absolute values may be different. The signs of the edge portion inclination angle θ_{J1} and the edge portion inclination angle θ_{J2} are the same or substantially the same and the absolute values may be different. The signs of the edge portion inclination angle θ_{J1} and the edge portion inclination angle θ_{J2} may be the same or substantially the same. Alternatively, for example, the above edge portion of the first curved region W1 is inclined with respect to the propagation axis, and the above edge portion of the second curved region W2 does not have to be inclined to the propagation axis.

The IDT electrode 58 includes the plurality of first electrode patterns 18 and the plurality of second electrode patterns 19 as in the fifth example embodiment. Therefore, the leakage of acoustic wave energy can be reduced or prevented and the Q factor can be increased.

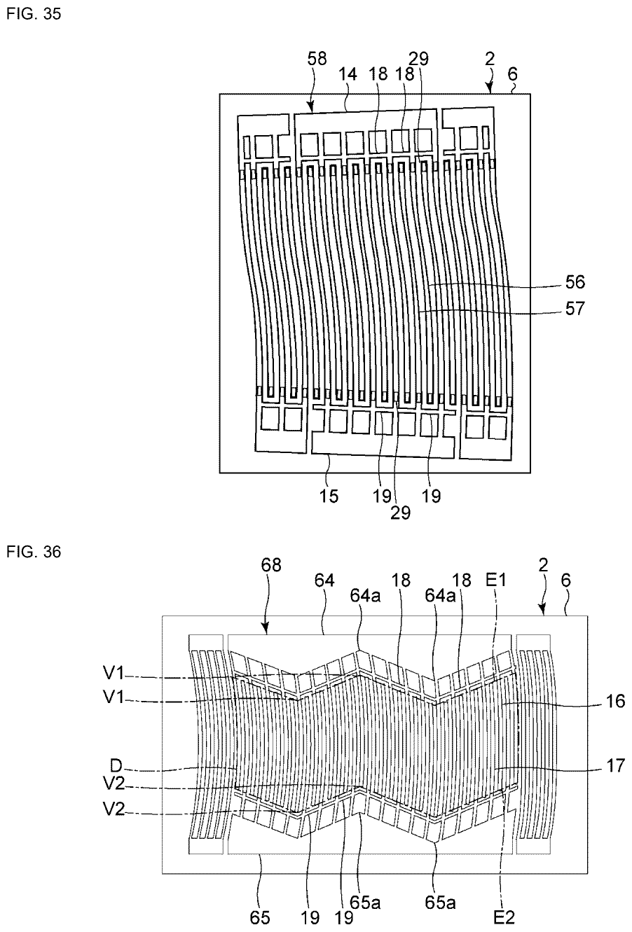

Meanwhile, in the sixth example embodiment as well, the low acoustic velocity region may be provided as in the second example embodiment. For example, in a modified example of the sixth example embodiment illustrated in FIG. 35, the mass addition film 29 is laminated on each of the electrode fingers of the IDT electrode 58 as in the second example embodiment. That is, the mass addition film 29 is laminated on each of the electrode fingers in each of the edge regions. This can establish the piston mode. Then, in this modified example as well, the IDT electrode 58 is similarly configured as the sixth example embodiment, and the plurality of first electrode patterns 18 and second electrode patterns 19 are provided. These can improve the main mode characteristics, can reduce or prevent the transverse mode and the spurious waves outside of the pass band, and can increase the Q factor.

FIG. 36 is a schematic plan view of an acoustic wave device according to a seventh example embodiment of the present invention.

The present example embodiment differs from the first example embodiment in a shape of an IDT electrode 68. Accordingly, a shape of each reflector also differs from that of the first example embodiment. The acoustic wave device of the present example embodiment has a similar configuration to that of the acoustic wave device 1 of the first example embodiment, except for the above point.

A portion of a first busbar 64 on the intersecting region D side includes a plurality of bent portions 64a. Similarly, a portion of a second busbar 65 on the intersecting region D side includes a plurality of bent portions 65a. However, the configuration may be such that at least one of the first busbar 64 and the second busbar 65 includes at least one bent portion.

The first envelope E1 includes a plurality of bent portions V1. The first envelope E1 has a wavy shape in which the plurality of bent portions V1 are connected with each other by straight lines. This makes a distance between the first busbar 64 and the intersecting region D constant.

Similarly, the second envelope E2 includes a plurality of bent portions V2. The second envelope E2 has a wavy shape in which the plurality of bent portions V2 are connected with each other by straight lines. This makes a distance between the second busbar 65 and the intersecting region D constant.

However, at least one of the first envelope E1 and the second envelope E2 may have a shape in which the plurality of bent portions are connected with each other by curved lines. Alternatively, a configuration may be such that at least one of the first envelope E1 and the second envelope E2 has a wavy shape.

In the present example embodiment, each of the first electrode patterns 18 extends parallel or substantially parallel to a direction in which a portion of the first busbar 64 on the intersecting region D side extends. As a result, the plurality of first electrode patterns 18 are arranged along the wavy shape. Similarly, each of f the second electrode patterns 19 extends parallel or substantially parallel to a direction in which a portion of the second busbar 65 on the intersecting region D side extends. As a result, the plurality of second electrode patterns 19 are arranged along the wavy shape.

In the present example embodiment, a shape of each of the plurality of electrode fingers of the IDT electrode 68 in plan view is an arc shape of a concentric circle including one fixed point as a common center.

In the present example embodiment as well, a distance between the tip portion of the electrode finger facing the electrode pattern and the electrode pattern is, for example, about 0.5\ or less. This can increase the Q factor.

In the first to seventh example embodiments, the resonant frequencies or the anti-resonant frequencies are made approximately coincident with each other in all of the excitation sections by adjusting the duty ratio. However, the resonant frequencies or the anti-resonant frequencies may be made approximately coincident with each other in all of the excitation sections by adjusting the electrode finger pitch. An example of this is described by an eighth example embodiment of the present invention.

The eighth example embodiment differs from the first example embodiment in that the duty ratio is constant in the IDT electrode, and that the electrode finger pitch is not constant. An acoustic wave device of the present example embodiment has a similar configuration to that of the acoustic wave device 1 of the first example embodiment except for the above points.

Here, the electrode finger pitch in the excitation section where θ_{C1_prop} is about 0° is defined as p0, the electrode finger pitch in any portion is defined as p1, and {(p1-p0)/p0×100 [%]} is defined as Δpitch [%], which is a change rate of the electrode finger pitch.

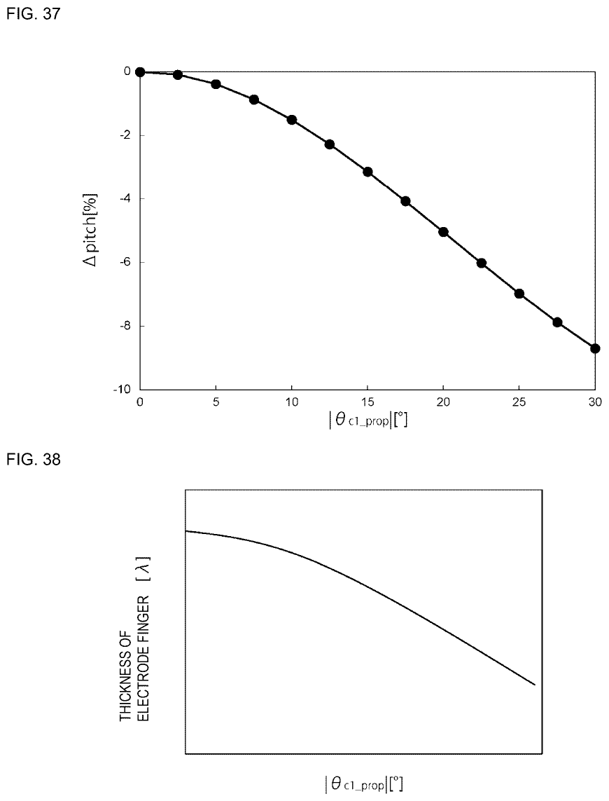

FIG. 37 is a diagram illustrating the relationship between the absolute value of the excitation angle |θ_{C1_prop}|and the change rate of electrode finger pitch Δpitch of the IDT electrode in the eighth example embodiment.

As illustrated in FIG. 37, in the present example embodiment, Δpitch is about 0% in the excitation section where the excitation angle θ_{C1_prop} is about 0° in the IDT electrode. Then, the larger the absolute value of the excitation angle |θ_{c1_prop}|, the larger Δpitch in the negative direction. That is, the larger the absolute value of the excitation angle |θ_{C1_prop}|, the narrower the electrode finger pitch. In the eighth example embodiment, a relationship between the absolute value of the excitation angle |θ_{C2_prop}| and Δpitch in the second curved region is the same as or similar to the relationship illustrated in FIG. 37. As a result, the resonant frequencies or the anti-resonant frequencies are approximately coincident with each other in all of the excitation sections in the first curved region and the second curved region. In addition, the leakage of acoustic wave energy can be reduced or prevented and the Q factor can be increased, as in the first example embodiment.

The relationship between the electrode finger pitch and the frequency of each mode differs, depending on the reverse-velocity surface of the piezoelectric substrate. Therefore, depending on the configuration of the piezoelectric substrate or the configuration on the piezoelectric substrate, when the absolute values of the excitation angles |θ_{C1_prop}| and |θ_{C2_prop}| become larger as the electrode finger pitch is wider, the resonant frequencies or the anti-resonant frequencies may coincide with each other in all of the excitation sections. An example of this can be the acoustic wave device in which the IDT electrode provided on the substrate including only the rotated Y-cut-4° X-propagation LINDO3 is embedded in the thick SiO₂ film, for the like. Alternatively, in the excitation section through which the reference line N1 passes and in which the excitation angles θ_{C1_prop} and θ_{C2_prop} are 0°, the value of the electrode finger pitch is not necessarily maximum or minimum.

In the first to eighth example embodiments, the resonant frequencies or the anti-resonant frequencies are made coincident with each other in all of the excitation sections by adjusting the duty ratio or the electrode finger pitch. However, the resonant frequencies or the anti-resonant frequencies may be made coincident with each other in all of the excitation sections by adjusting thicknesses of the plurality of electrode fingers. An example of this is illustrated in a ninth example embodiment of the present invention.

In the IDT electrode, the ninth example embodiment differs from the first example embodiment in that the duty ratio is constant, and that the thicknesses of the plurality of electrode fingers are not constant. Except for the above points, an acoustic wave device of the present example embodiment has a similar configuration of that of the acoustic wave device 1 of the first example embodiment.

FIG. 38 is a diagram illustrating the relationship between the absolute value of the excitation angle |θ_{C1_prop}| and the thicknesses of the electrode fingers of the IDT electrode in the ninth example embodiment.

As illustrated in FIG. 38, in the first curved region of the IDT electrode, the larger the absolute value of the excitation angle |θ_{C1_prop}|, the thinner the thicknesses of the first electrode finger and the second electrode finger. In the ninth example embodiment, the relationship between the absolute value of the excitation angle |θ_{C2_prop}| and the thicknesses of the first electrode finger and the second electrode finger in the second curved region is the same as or similar to the relationship illustrated in FIG. 38. As a result, the resonant frequencies or the anti-resonant frequencies are approximately coincident with each other in all of the excitation sections in the first curved region and the second curved region. In addition, the leakage of acoustic wave energy can be reduced or prevented and the Q factor can be increased, as in the first example embodiment.

The relationship between the thicknesses of the first electrode finger and the second electrode finger and the frequency of each mode differs, depending on the reverse-velocity surface of the piezoelectric substrate. Therefore, depending on the configuration of the piezoelectric substrate or the configuration on the piezoelectric substrate, when the absolute values of the excitation angles |θ_{C1_prop}| and |θ_{C2_prop}| become larger as the thickness of each of the electrode fingers is thicker, the resonant frequencies or the anti-resonant frequencies may coincide with each other in all of the excitation sections. An example of this can be the acoustic wave device in which the IDT electrode provided on the substrate including only the rotated Y-cut-4° X-propagation LINbO₃ is embedded thick SiO₂ film, or the like. Alternatively, in the excitation section through which the reference line N1 passes and in which the excitation angles θ_{C1_prop} and θC2_prop are about 0°, thickness values of the thickness of the first electrode finger and the thickness of the second electrode finger are not necessarily maximum or minimum.

In the first to ninth example embodiments, according to the configuration of the IDT electrodes, the resonant frequencies or the anti-resonant frequencies are made coincident with each other in all of the excitation sections. However, the resonant frequencies or the anti-resonant frequencies may be made coincident with each other in all of the excitation sections by adjusting the thickness of the dielectric film covering the IDT electrode. An example of this is described by a tenth example embodiment of the present invention and a modified example thereof.

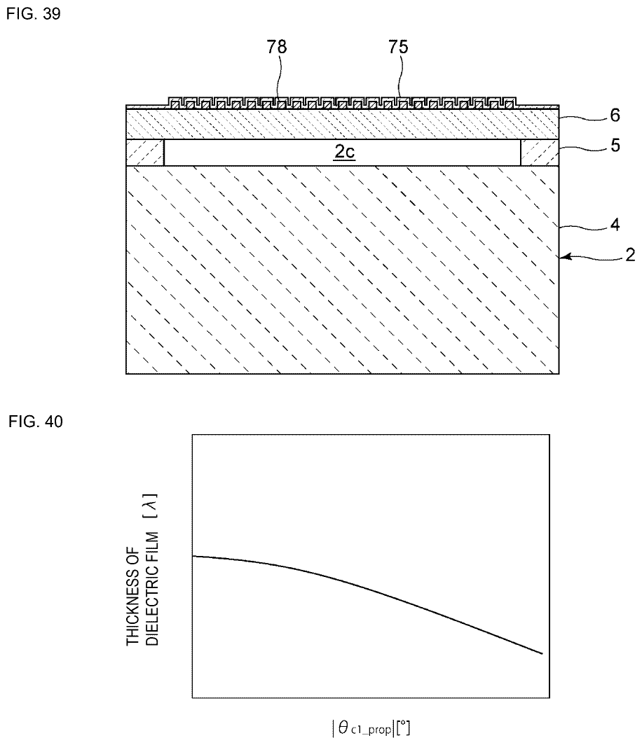

FIG. 39 is a schematic elevational cross-sectional view of an acoustic wave device according to the tenth example embodiment. FIG. 39 illustrates a cross section corresponding to the portions illustrated in FIG. 2. The same applies to schematic elevational cross-sectional views other than FIG. 39.

The present example embodiment differs from the first example embodiment in that the duty ratio is constant in an IDT electrode 78. The present example embodiment also differs from the first example embodiment in that a dielectric film 75 is provided so as to cover the IDT electrode 78 on the piezoelectric body layer 6. Except for the above points, the acoustic wave device of the present example embodiment has a similar configuration to that of the acoustic wave device 1 of the first example embodiment.

The acoustic velocity of a transversal wave propagating through the dielectric film 75 of the present example embodiment is lower than the acoustic velocity of the main mode when propagating through the dielectric film 75. A thickness of the dielectric film 75 varies depending on the excitation angle θ_{C1_prop} of the excitation section in the first curved region covered by the dielectric film 75. Similarly, the thickness of the dielectric film 75 varies depending on the excitation angle θ_{C2_prop} of the excitation section in the second curved region covered by the dielectric film 75.

FIG. 40 is a diagram illustrating a relationship between the absolute value of the excitation angle |θc prop| in the excitation section of the first curved region covered by the dielectric film and the thickness of the dielectric film in the tenth example embodiment.

As illustrated in FIG. 40, in the present example embodiment, the larger the absolute value of the excitation angle |θ_{C1_prop}| in the excitation section of the first curved region covered by the dielectric film 75, the thinner the thickness of the dielectric film 75. In the tenth example embodiment, the relationship between the absolute value of the excitation angle |θ_{C2_prop}| in the excitation section of the second curved region covered by the dielectric film and the thickness of the dielectric film 75 is also the same as or similar to the relationship illustrated in FIG. 40. As a result, the resonant frequencies or the anti-resonant frequencies are approximately coincident with each other in all of the excitation sections in the first curved region and the second curved region. In addition, the leakage of acoustic wave energy can be reduced or prevented and the Q factor can be increased, as in the first example embodiment.

In the tenth example embodiment, the acoustic velocity of the transversal wave propagating through the dielectric film 75 is lower than the acoustic velocity of the main mode when propagating through the dielectric film 75. However, the relationship of acoustic velocities of waves propagating through the dielectric film is not limited to the above. The modified example of the tenth example embodiment is described below that differs from the tenth example embodiment only in the acoustic velocity of the transversal wave propagating through the dielectric film and in a thickness change.

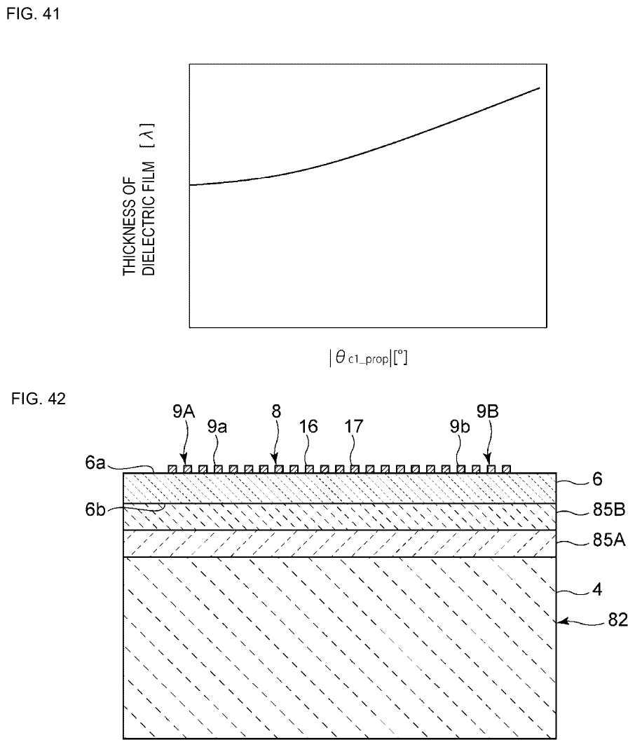

In the modified example of the tenth example embodiment, the acoustic velocity of the transversal wave propagating the dielectric film is higher than the acoustic velocity of the main mode when propagating through the dielectric film. Then, in this modified example, the relationship between the absolute value of the excitation angle |θ_{C1_prop}| in the excitation section of the first curved region covered by the dielectric film and the thickness of the dielectric film is as illustrated in FIG. 41. More specifically, the larger the absolute value of the excitation angle |θ_{C1_prop}| in the excitation section of the first curved region covered by the dielectric film, the thicker the thickness of the dielectric film. In this modified example, the relationship between the absolute value of the excitation angle |θ_{C2_prop}| in the excitation section of the second curved region covered by the dielectric film and the thickness of the dielectric film is also the same as or similar to the relationship illustrated in FIG. 41. As a result, the resonant frequencies or the anti-resonant frequencies are approximately coincident with each other in all of the excitation sections in the first curved region and the second curved region. In addition, the leakage of acoustic wave energy can be reduced or prevented and the Q factor can be increased, as in the tenth example embodiment.

Depending on the configuration of the piezoelectric substrate, a value of the thickness of the portion of the dielectric film covering the excitation section, through which the reference line passes, is not necessarily maximum or minimum.

Meanwhile, a lamination structure of the piezoelectric substrate is not limited to the configuration illustrated in FIG. 2. According to an eleventh example embodiment of the present invention, an example of an acoustic wave device is illustrated that includes a piezoelectric substrate different from that of the first example embodiment.

FIG. 42 is a schematic elevational cross-sectional view of the acoustic wave device according to the eleventh example embodiment.

This example embodiment differs from the first example embodiment in the lamination structure of a piezoelectric substrate 82. The acoustic wave device of the present example embodiment has a similar configuration to that of the acoustic wave device of the first example embodiment, except for the above point.

The piezoelectric substrate 82 includes the supporting substrate 4, a high acoustic velocity film 85A, a low acoustic velocity film 85B, and the piezoelectric body layer 6. The high acoustic velocity film 85A is provided on the supporting substrate 4. The low acoustic velocity film 85B is provided on the high acoustic velocity film 85A. The piezoelectric body layer 6 is provided on the low acoustic velocity film 85B.

The high acoustic velocity film 85A is a film with a relatively high acoustic velocity. More specifically, an acoustic velocity of a bulk wave propagating through the high acoustic velocity film 85A is higher than that of the acoustic wave propagating through the piezoelectric body layer 6. As materials of the high acoustic velocity film 85A, for example, a piezoelectric body such as aluminum nitride, lithium tantalate, lithium niobate, quartz crystal, or the like, ceramics such as alumina, sapphire, magnesia, silicon nitride, silicon carbide, zirconia, cordierite, mullite, steatite, forsterite, or the like, ceramics such as alumina, sapphire, magnesia, silicon nitride, silicon carbide, zirconia, cordierite, mullite, steatite, forsterite, spinel, sialon, or the like, a dielectric such as aluminum oxide, silicon oxynitride, DLC (diamond-like carbon), diamond or glass, or the like, or a semiconductor such as silicon, or a material with a main component of the materials described above can be used. Spinel includes, for example, an aluminum compound including one or more element of Mg, Fe, Zn, Mn, or the like and oxygen. Examples of spinel can include, for example, MgAl₂O₄, FeAl₂O₄, ZnAl₂O₄, and MnAl₂O₄.

The low acoustic velocity film 85B is a film with a relatively low acoustic velocity. More specifically, an acoustic velocity of a bulk wave propagating through the low acoustic velocity film 85B is lower than that of the bulk wave propagating through the piezoelectric body layer 6. As materials of the low acoustic velocity film 85B, for example, glass, silicon oxide, silicon oxynitride, lithium oxide, tantalum oxide, or a dielectric such as a compound of silicon oxide to which fluorine, carbon, or boron is added, or a material with a main component of the materials described above can be used.

In the eleventh example embodiment, the high acoustic velocity film 85A, the low acoustic velocity film 85B, and the piezoelectric body layer 6 are laminated in this order in the piezoelectric substrate 82. This makes it possible to effectively confine the energy of acoustic waves to the piezoelectric body layer 6 side. Therefore, loss in a stopband can be reduced. A stopband is a region where an acoustic wave is confined in a metal grating of a periodic structure, so that a wavelength of the acoustic wave is constant. An upper end of the stopband is the end of the high frequency side of the stopband. The stopband is a band from the resonant frequency to a frequency of the upper end of the stopband.

In addition, as in the first example embodiment, it is also possible to reduce or prevent the leakage of acoustic wave energy from the intersecting region side to the busbar side. Therefore, the Q factor can be increased effectively. Further, the transverse mode can be reduced or prevented.

The above-described advantageous effects of the eleventh example embodiment are described by a comparison of the eleventh example embodiment with the second reference example illustrated in FIG. 6. According to the comparison, the design parameters of the acoustic wave device of the eleventh example embodiment are as follows.

Supporting substrate 4; Material . . . Si, plane orientation . . . (111), ψ at Euler angles (φ, θ, and ψ): about 73° High acoustic velocity film 85A; Material . . . SiN, thickness . . . about 0.15λ

Low acoustic velocity film 85B; Material . . . SiO₂, thickness . . . about 0.15λ

Piezoelectric body layer 6; Material . . . Rotated Y-cut 55° X-propagation LiTaO₃, thickness. . . about 0.2λ

IDT electrode 8; Material . . . Al, thickness . . . about 0.05λ

Ellipse coefficient in the shape of the electrode finger α12/α11; about 1

Ellipse coefficient in the shape of the electrode finger x22/α21; about 1

Wavelength λ; about 2 μm

Number of pairs of the electrode fingers of the IDT electrode 8; 80 pairs

Duty ratio; about 0.5 in the excitation section where the angle θ_{C1} and the angle θ_{C2} are about 0°

Intersecting angle θ_{C1_AP}; about 10° Intersecting angle θ_{C2_AP}; about 10° I-P gap; about 0.135λ

Width of the first electrode pattern 18 and the second electrode pattern 19; about 0.2λ

B-P gap; about 2λ

Reflector 9A and reflector 9B; number of pairs of the reflector electrode fingers . . . 20 pairs

The design parameters of the acoustic wave device of the second reference example are the same as or similar to the design parameters of the acoustic wave device according to the eleventh example embodiment, except for the parameters related to the electrode patterns. In the second reference example, the distance between the electrode fingers and the busbar is about 2λ.

The impedance frequency characteristics and the relationship between the frequency and the Q factor of each of the acoustic wave devices of the eleventh example embodiment and the second reference example are determined.

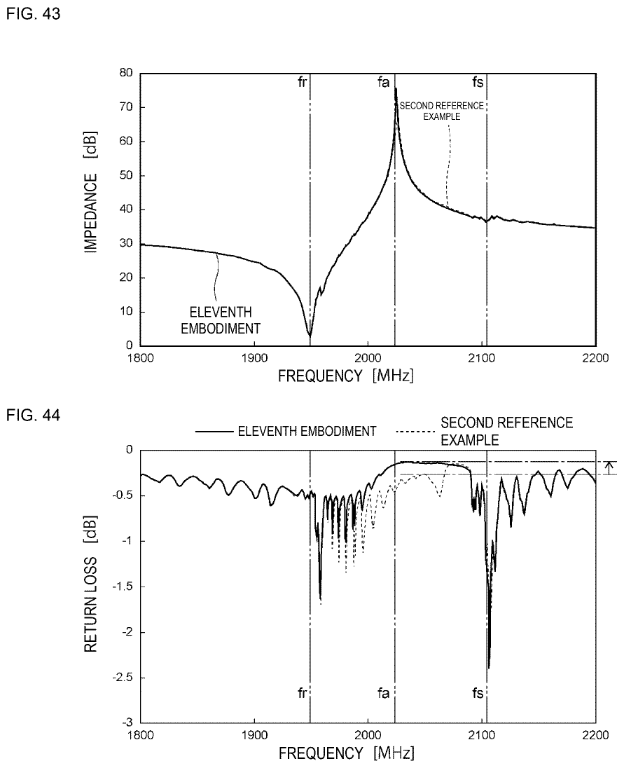

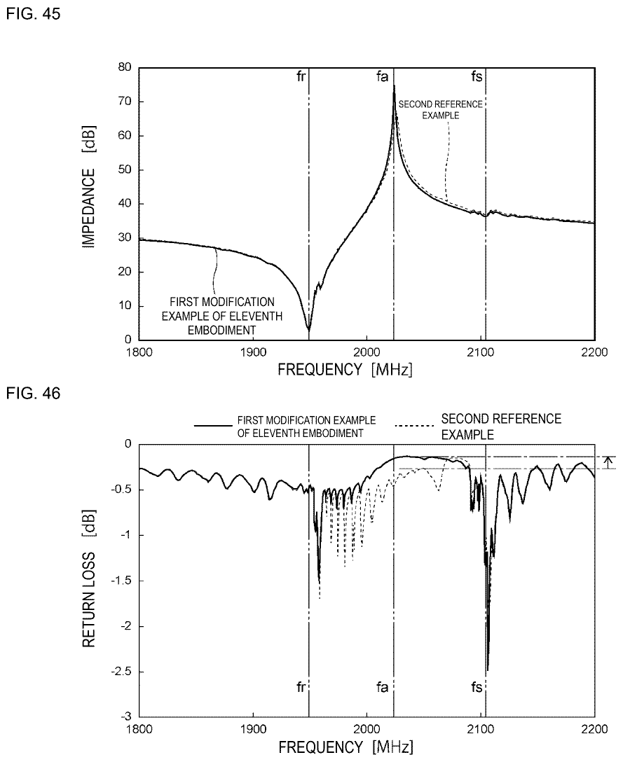

FIG. 43 is a diagram illustrating the impedance frequency characteristics in the eleventh example embodiment and the second reference example. FIG. 44 is a diagram illustrating a relationship between a frequency and a return loss in the eleventh example embodiment and the second reference example. Note that in FIGS. 43 and 44, fr is the resonant frequency, fa is the anti-resonant frequency, and fs is the frequency at the upper end of the stopband. The same also applies to FIGS. 45 and 46 to be described below.

As illustrated in FIG. 43, it can be seen that the impedance ratio is larger in the eleventh example embodiment than in the second reference example. This is because the Q factor can be made higher in the eleventh example embodiment.

As illustrated in FIG. 44, in the second reference example, a large ripple due to the transverse mode occurs between the resonant frequency and the anti-resonant frequency. In contrast, it can be seen that the transverse mode is reduced or prevented more in the eleventh example embodiment than in the second reference example. In addition, it can be seen that more loss in the stopband can be reduced in the eleventh example embodiment than in the second reference example.

Similar advantageous effects to those described above can also be obtained even when only the configuration of the IDT electrode is different from that of the eleventh example embodiment. An example of this is described by a comparison of a first modified example of the eleventh example embodiment with the second reference example. The IDT electrode in the first modified example has the same or similar configuration as that of the IDT electrode 28 in the second modified example of the second example embodiment illustrated in FIG. 17. That is, each of the electrode fingers includes the wide portion in the first edge region H1 and the second edge region H2. As a result, the low acoustic velocity region is provided in each of the edge regions.

The design parameters of the acoustic wave device of the first modified example according to the comparison are the same as or similar to the design parameters of the acoustic wave device of the eleventh example embodiment according to the comparison in FIGS. 43 and 44, except for each of the edge regions. Specifically, for example, in the first modified example, a dimension of each of the edge regions in the direction in which the electrode fingers extend is about 0.75λ. The duty ratio in each of the edge regions is, for example, about 0.67. The design parameters of the acoustic wave device of the second reference example are the same as or similar to the design parameters according to the comparison in FIGS. 43 and 44.

FIG. 45 is a diagram illustrating the impedance frequency characteristics in a first modified example of the eleventh example embodiment and the second reference example. FIG. 46 is a diagram illustrating the relationship between the frequency and the return loss in the first modified example of the eleventh example embodiment and the second reference example.

As illustrated in FIG. 45, it can be seen that the impedance ratio is larger in the first modified example than in the second reference example. This is because the Q factor can be made higher in the first modified example, as in the eleventh example embodiment.

As illustrated in FIG. 46, it can be seen that the transverse mode can be reduced or prevented more effectively in the first modified example than in the second reference example. This is because the piston mode is established in the first modified example. In addition, it can be seen that more loss in the stopband can be reduced in this modified example than in the second reference example. The advantageous effects of the eleventh example embodiment and the first modified example can be similarly obtained when the dielectric film is provided on the piezoelectric substrate.

A second modified example and a third modified example of the eleventh example embodiment that differs from the eleventh example embodiment only in the lamination structure of the piezoelectric substrate are described below. In the second modified example and the third modified example as well, the Q factor can be increased, as in the eleventh example embodiment.

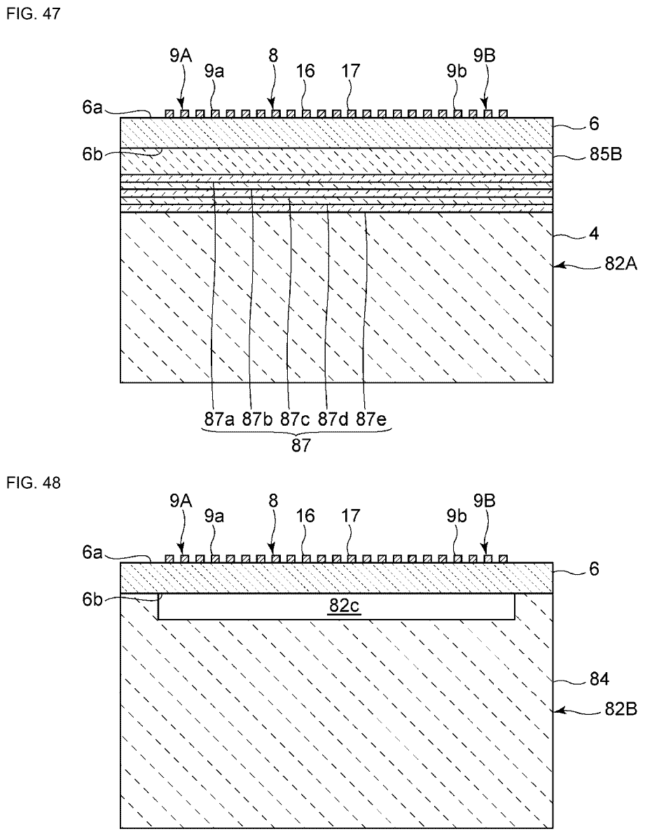

In the second modified example illustrated in FIG. 47, a piezoelectric substrate 82A includes the supporting substrate 4, an acoustic reflection film 87, the low acoustic velocity film 85B, and the piezoelectric body layer 6. The acoustic reflection film 87 is provided on the supporting substrate 4. The low acoustic velocity film 85B is provided on the acoustic reflection film 87. The piezoelectric body layer 6 is provided on the low acoustic velocity film 85B.

The acoustic reflection film 87 is a multilayer body including a plurality of acoustic impedance layers. Specifically, the acoustic reflection film 87 includes a plurality of low acoustic impedance layers and a plurality of high acoustic impedance layers. The high acoustic impedance layer is a layer with relatively high acoustic impedance. More specifically, the plurality of high acoustic impedance layers of the acoustic reflection film 87 is a high acoustic impedance layer 87a, a high acoustic impedance layer 87c, and a high acoustic impedance layer 87e. In contrast, the low acoustic impedance layer is a layer with relatively low acoustic impedance. More specifically, the plurality of low acoustic impedance layers of the acoustic reflection film 87 is a low acoustic impedance layer 87b and a low acoustic impedance layer 87d. The low acoustic impedance layers and the high acoustic impedance layers are laminated alternately. Note that the high acoustic impedance layer 87a is a layer located closest to the piezoelectric body layer 6 in the acoustic reflection film 87.

The acoustic reflection film 87 includes, for example, two low acoustic impedance layers and three high acoustic impedance layers. However, it is sufficient if the acoustic reflection film 87 includes at least one layer each of the low acoustic impedance layers and the high acoustic impedance layers.

As a material of the low acoustic impedance layer, for example, silicon oxide or aluminum, or the like can be used. As a material of the high acoustic impedance layer, for example, a metal such as platinum or tungsten or a dielectric such as aluminum nitride or silicon nitride, or the like can be used. The material of the low acoustic velocity film 85B may be the same as the material of the low acoustic impedance layer.

In the third modified example illustrated in FIG. 48, a piezoelectric substrate 82B includes a supporting substrate 84 and the piezoelectric body layer 6. The piezoelectric body layer 6 is provided directly on the supporting substrate 84. More specifically, the supporting substrate 84 includes a recessed portion. The piezoelectric body layer 6 is provided on the supporting substrate 84 so as to close the recessed portion. This defines a hollow portion 82c in the piezoelectric substrate 82B. A portion of the piezoelectric body layer 6 and a portion of the supporting substrate 84 are opposed to each other with the hollow portion 82c interposed therebetween. The hollow portion 82c overlaps with at least a portion of the IDT electrode 8 in plan view.

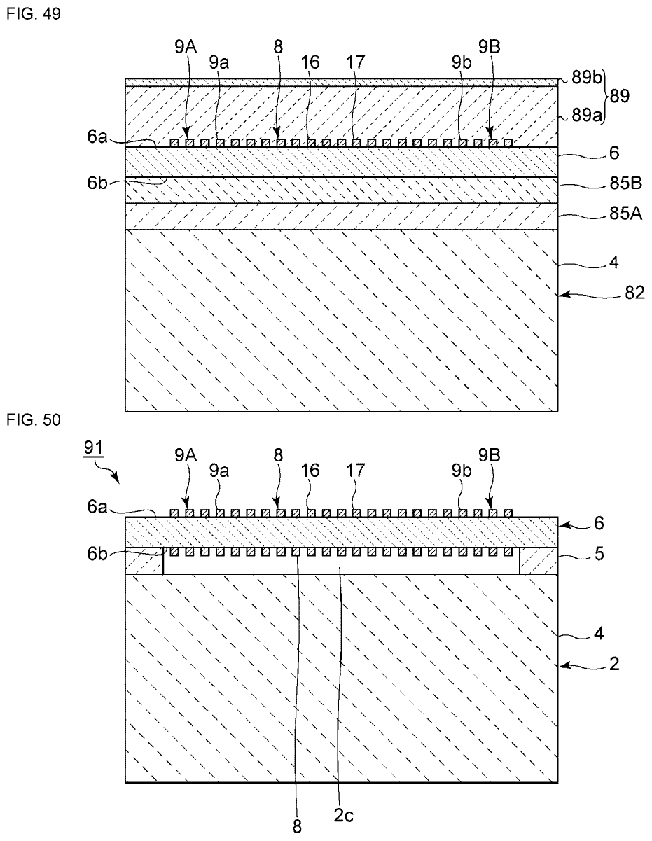

Meanwhile, the IDT electrode 8 illustrated in FIG. 42 may be embedded in a protective film. In a fourth modified example of the eleventh example embodiment illustrated in FIG. 49, a protective film 89 is provided on the piezoelectric body layer 6 so as to cover the IDT electrode 8. A thickness of the protective film 89 is thicker than that of the IDT electrode 8. The IDT electrode 8 is embedded in the protective film 89. This makes it difficult for the IDT electrode 8 to be damaged.

The protective film 89 includes a first layer 89a and a second layer 89b. The IDT electrode 8 is embedded in the first layer 89a. The second layer 89b is provided on the first layer 89a. This makes it possible to obtain a plurality of advantageous effects by the protective film 89. Specifically, in this modified example, for example, silicon oxide is used as a material of the first layer 89a. This can reduce an absolute value of a temperature coefficient of frequency (TCF) in the acoustic wave device. Therefore, temperature characteristics of the acoustic wave device can be improved. Silicon nitride is used for the second layer 89b, for example. This can increase moisture resistance. In addition, in this modified example as well, the Q factor can be increased, as in the eleventh example embodiment.

The materials of the first layer 89a and the second layer

89b are not limited to the above. The protective film 89 may be a single layer or a multilayer body including three or more layers.

FIG. 50 is a schematic elevational cross-sectional view of an acoustic wave device according to a twelfth example embodiment of the present invention.

The present example embodiment differs from the first example embodiment in that the IDT electrode 8 is provided on both the first main surface 6a and the second main surface 6b of the piezoelectric body layer 6. The IDT electrode 8 provided on the second main surface 6b is located in the hollow portion 2c. Except for the above point, an acoustic wave device 91 of the present example embodiment has a similar configuration to that of the acoustic wave device 1 of the first example embodiment.

The IDT electrode 8 provided on the first main surface 6a of the piezoelectric body layer 6 and the IDT electrode 8 provided on the second main surface 6b are opposed to each other with the piezoelectric body layer 6 interposed therebetween. In the present example embodiment as well, as in the first example embodiment, the plurality of first electrode patterns and the plurality of the second electrode patterns are provided. This makes it possible to reduce or prevent the leakage of acoustic wave energy and increase the @ factor.

The IDT electrodes 8 provided on the first main surface 6a and the second main surface 6b of the piezoelectric body layer 6 may have mutually different design parameters, for example.

First to third modified examples of the twelfth example embodiment, which differ from the twelfth example embodiment only in at least one of the configuration of the electrode provided on the second main surface of the piezoelectric body layer and the lamination structure of the piezoelectric substrate, are described below. In the first to third modified examples as well, the Q factor can be increased, as in the twelfth example embodiment.

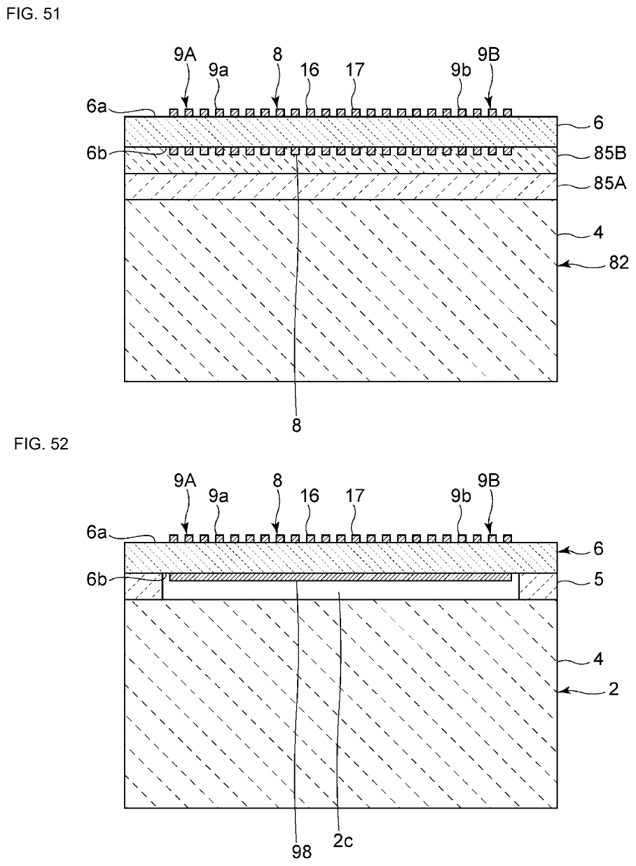

In the first modified example illustrated in FIG. 51, the piezoelectric substrate 82 is configured the same as or similar to the eleventh example embodiment. Specifically, the piezoelectric substrate 82 includes the supporting substrate 4, the high acoustic velocity film 85A, the low acoustic velocity film 85B, and the piezoelectric body layer 6. The IDT electrode 8 provided on the second main surface 6b of the piezoelectric body layer 6 is embedded in the low acoustic velocity film 85B.

In the second modified example illustrated in FIG. 52, a plate-shaped electrode 98 is provided on the second main surface 6b of the piezoelectric body layer 6. The electrode 98 is located in the hollow portion 2c. The IDT electrode 8 and the electrode 98 are opposed to each other with the piezoelectric body layer 6 interposed therebetween.

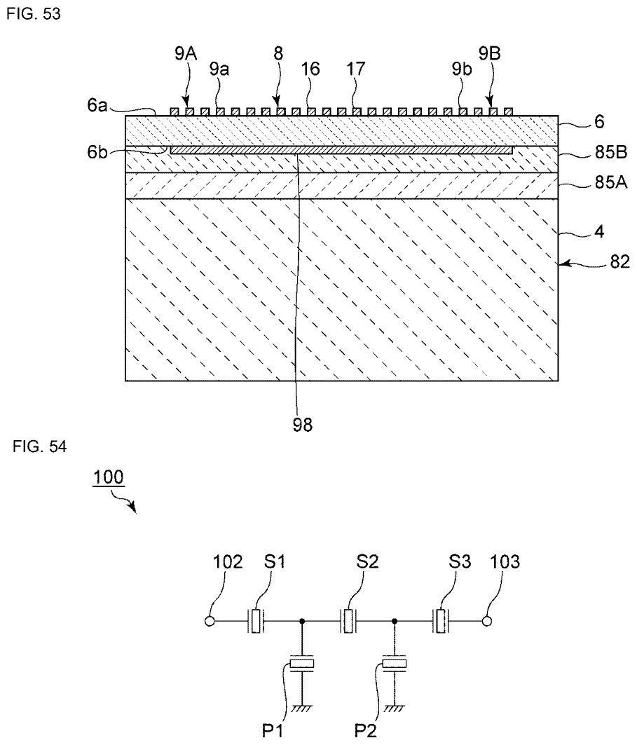

In the third modified example illustrated in FIG. 53, the piezoelectric substrate 82 is configured the same as or similar to the first modified example, and the electrode 98 the same as or similar to that of the second modified example is provided on the second main surface 6b of the piezoelectric body layer 6. The electrode 98 is embedded in the low acoustic velocity film 85B.

The acoustic wave device according to the present invention can be used in a filter device, for example. An example of this is described below.

FIG. 54 is a circuit diagram of a filter device according to a thirteenth example embodiment of the present invention.

A filter device 100 of the present example embodiment is a ladder filter, for example. The filter device 100 includes a first signal terminal 102 and a second signal terminal 103, and a plurality of series arm resonators and a plurality of parallel arm resonators. In the filter device 100, all of the series arm resonators and all of the parallel arm resonators are acoustic wave resonators. Furthermore, all of the series arm resonators and all of the parallel arm resonators are acoustic wave devices according to example embodiments of the present invention. However, it is sufficient that at least one acoustic wave resonator of the acoustic wave resonators of the filter device 100 is an acoustic wave device according to an example embodiment of the present invention.

The first signal terminal 102 is an antenna terminal. The antenna terminal is connected to an antenna. However, the first signal terminal 102 does not necessarily have to be an antenna terminal. The first signal terminal 102 and the second signal terminal 103 may be configured as an electrode pad, for example, or may be configured as a wiring line, for example.

Specifically, the plurality of series arm resonators of the present example embodiment are a series arm resonator S1, a series arm resonator S2, and a series arm resonator S3. The plurality of series arm resonators are connected in series to each other between the first signal terminal 102 and the second signal terminal 103. Specifically, the plurality of parallel arm resonators of the present example embodiment are a parallel arm resonator P1 and a parallel arm resonator P2. The parallel arm resonator P1 is connected between a connecting point between the series arm resonator S1 and the series arm resonator S2, and a ground potential. The parallel arm resonator P2 is connected between a connecting point between the series arm resonator S2 and the series arm resonator S3, and the ground potential. The circuit configuration of the filter device 100 is not limited to the above. The filter device 100 may include, for example, a longitudinally coupled resonator acoustic wave filter.

The acoustic wave resonators in the filter device 100 are acoustic wave devices according to example embodiments of the present invention. Therefore, in the acoustic wave resonators of the filter device 100, the leakage of acoustic wave energy can be reduced or prevented and the Q factor can be increased. Consequently, filter characteristics of the filter device 100 can be improved.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate including a piezoelectric body layer; and
an IDT electrode on the piezoelectric body layer and including a pair of busbars and a plurality of electrode fingers; wherein
the pair of busbars includes a first busbar and a second busbar opposed to each other, the plurality of electrode fingers include a plurality of first electrode fingers and a plurality of second electrode fingers, one end of each of the plurality of first electrode fingers is connected to the first busbar, one end of each of the plurality of second electrode fingers is connected to the second busbar, and the plurality of first electrode fingers and the plurality of second electrode fingers are interdigitated with each other;
an imaginary line connecting tip portions of the plurality of second electrode fingers is a first envelope, an imaginary line connecting tip portions of the plurality of first electrode fingers is a second envelope, and a region between the first envelope and the second envelope in the IDT electrode is an intersecting region;
the acoustic wave device further includes a plurality of electrode patterns on the piezoelectric body layer and between at least one of the first busbar and the intersecting region and the second busbar and the intersecting region;
of the plurality of electrode fingers, a tip portion of at least one of the plurality of first electrode fingers or a tip portion of at least one of the plurality of second electrode fingers faces at least one of the plurality of electrode patterns;
in plan view, a shape of the plurality of first electrode fingers and a shape of the plurality of second electrode fingers each include a curved portion in the intersecting region; and
when a wavelength defined by an electrode finger pitch of the IDT electrode is λ, a distance between the tip portion of the electrode finger among the plurality of electrode fingers that faces the at least one of plurality of electrode patterns and the at least one of plurality of electrode patterns is about 0.5λ or less.

2. The acoustic wave device according to claim 1, wherein
the intersecting region includes a first edge region including the first envelope, a second edge region including the second envelope, and a central region interposed between the first edge region and the second edge region; and
a low acoustic velocity region is provided in at least a portion of at least one of the first edge region and the second edge region, an acoustic velocity of the low acoustic velocity region being lower than an acoustic velocity in the central region.

3. The acoustic wave device according to claim 2, wherein at least one of the plurality of electrode fingers includes a wide portion that is wider than a width in the central region in at least one of the first edge region and the second edge region, so that the low acoustic velocity region is provided.

4. The acoustic wave device according to claim 2 further comprising:
a mass addition film overlapping with at least one of the plurality of first electrode fingers and the plurality of second electrode fingers in at least one of the first edge region and the second edge region when viewed in plan view defines the low acoustic velocity region.

5. The acoustic wave device according to claim 2 further comprising:
a high acoustic velocity film in the central region; wherein
an acoustic velocity in the central region is higher than an acoustic velocity in the first edge region and the second edge region and the low acoustic velocity region is provided in both the first edge region and the second edge region.

6. The acoustic wave device according to claim 2, wherein the low acoustic velocity region is provided in an entirety or substantially an entirety of both of the first edge region and the second edge region.

7. The acoustic wave device according to claim 2, wherein the low acoustic velocity region is provided in at least a portion of only one of the first edge region and the second edge region.

8. The acoustic wave device according to claim 7, wherein
the plurality of electrode patterns are provided only between the first busbar and the plurality of second electrode fingers; and
the low acoustic velocity region is provided in at least a portion of only the second edge region.

9. The acoustic wave device according to claim 2, wherein
some of the plurality of second electrode fingers face the electrode patterns;
the low acoustic velocity region is provided in a portion of the first edge region;
at least one of the plurality of second electrode fingers is provided in a portion of the first edge region where the low acoustic velocity region is not provided; and
a tip portion of the at least one of the plurality of second electrode fingers faces at least one of the plurality of electrode patterns.

10. The acoustic wave device according to claim 2 further comprising:
at least one offset electrode including one end connected to the first busbar; wherein
the low acoustic velocity region is provided in a portion of the first edge region;
at least one of the plurality of second electrode fingers is provided in a portion of the first edge region where the low acoustic velocity region is not provided; and
the at least one of the plurality of second electrode fingers faces the at least one offset electrode.

11. The acoustic wave device according to claim 1, wherein
the plurality of electrode patterns are provided both between the first busbar and the intersecting region and between the second busbar and the intersecting region; and
tip portions of all of the plurality of first electrode fingers and tip portions of all of the plurality of second electrode fingers face the plurality of electrode patterns.

12. The acoustic wave device according to claim 1, wherein the plurality of electrode patterns are provided only either between the first busbar and the intersecting region or between the second busbar and the intersecting region.

13. The acoustic wave device according to claim 1, wherein at least one of the plurality of electrode patterns has a rectangular or substantially rectangular shape in plan view extending parallel or substantially parallel to a busbar of the pair of busbars that faces the at least one of the plurality of electrode patterns, and is connected to both of adjacent electrode fingers of the plurality of electrode fingers connected to the busbar.

14. The acoustic wave device according to claim 1, wherein at least one of the plurality of electrode patterns has a rectangular or substantially rectangular shape in plan view extending parallel or substantially parallel to a busbar of the pair of busbars that faces the at least one of the plurality of electrode patterns, and is connected to only one of adjacent electrode fingers of the plurality of electrode fingers connected to the busbar.

15. The acoustic wave device according to claim 1, wherein at least one of the plurality of electrode patterns has a rectangular or substantially rectangular shape in plan view extending parallel or substantially parallel to a busbar of the pair of busbars that faces the at least one of the plurality of electrode patterns, and is not connected to any of adjacent electrode fingers of the plurality of electrode fingers connected to the busbar.

16. The acoustic wave device according to claim 1, wherein at least one of the plurality of electrode patterns has a shape in plan view that includes a side not extending parallel or substantially parallel to a busbar of the pair of busbars that faces the at least one of the plurality of electrode patterns, and is connected to both of adjacent electrode fingers of the plurality of electrode fingers connected to the busbar.

17. The acoustic wave device according to claim 1, wherein at least one of the plurality of electrode patterns has a shape in plan view that includes a side not extending parallel or substantially parallel to a busbar of the pair of busbars that faces the at least one of the plurality of electrode patterns, and is connected to only one of adjacent electrode fingers of the plurality of electrode fingers connected to the busbar.

18. The acoustic wave device according to claim 1, wherein at least one of the plurality of electrode patterns has a shape in plan view that includes a side not extending parallel or substantially parallel to a busbar of the pair of busbars that faces the at least one of the plurality of electrode patterns, and is not connected to any of the electrode fingers that are adjacent to each other and connected to the busbar.

19. The acoustic wave device according to claim 1, wherein
a piezoelectric single crystal is included in the piezoelectric body layer;
the piezoelectric body layer includes a propagation axis; and
the first envelope extends at an angle with respect to the propagation axis.

20. The acoustic wave device according to claim 19, wherein
the second envelope extends at an angle with respect to the propagation axis;
absolute values of angles at which the first envelope and the second envelope are inclined with respect to the propagation axis are about 90° or less; and
the first envelope and the second envelope extend at an angle in opposite directions to each other with respect to the propagation axis.

21. The acoustic wave device according to claim 1, wherein at least one of the first envelope and the second envelope includes at least one bent portion at which an extending direction changes.

22. The acoustic wave device according to claim 1, wherein the plurality of first electrode fingers and the plurality of second electrode fingers in plan view each include at least two curved portions in which the plurality of first electrode fingers and the plurality of second electrode fingers are bent in different directions in the intersecting region, and include at least one inflection point.

23. The acoustic wave device according to claim 22, wherein
the at least two curved portions each include an arc or elliptical arc shape; and
the intersecting region includes at least two curved regions at which the plurality of first electrode fingers and the plurality of second electrode fingers in plan view each include a single arc or elliptical arc shape.

24. The acoustic wave device according to claim 23, wherein
one curved region of the plurality of curved regions includes the first envelope;
in each of the plurality of curved regions, when a center of a circle including the arc shape of each of the plurality of first electrode fingers and the plurality of second electrode fingers or a center of gravity of two foci of an ellipse including the elliptical arc is defined as a fixed point, and a portion on any straight line passing through the fixed point in each of the plurality of curved regions is defined as an excitation section, an extended line of the first envelope passes the fixed point in the curved region;
when a straight line including the first envelope and the extended line of the first envelope is defined as a reference line, an angle between a straight line that passes through the fixed point and the excitation section in the curved region including the first envelope and the reference line is defined, and an excitation angle of an angle between the reference line and an excitation direction of an acoustic wave at an intersection between the straight line that passes through the fixed point and the excitation section in the curved region and the electrode fingers is defined, at least one of a duty ratio, an electrode finger pitch, or a thicknesses of the plurality of first electrode fingers and the plurality of second electrode fingers changes according to the respective angle or the excitation angle so that resonant frequencies or anti-resonant frequencies in all of the excitation sections of the one curved region are approximately coincident with each other.

25. The acoustic wave device according to claim 23 further comprising:
a dielectric film on the piezoelectric body layer and covering the IDT electrode; wherein
one curved region of the plurality of curved regions includes the first envelope;
in each of the plurality of curved regions, when a center of a circle including the arc shape of each of the plurality of first electrode fingers and the plurality of second electrode fingers or a center of gravity of two foci of an ellipse including the elliptical arc is defined as a fixed point, and a portion on any straight line passing through the fixed point in each of the plurality of curved regions is defined as an excitation section, an extended line of the first envelope passes the fixed point in the curved region;
when a straight line including the first envelope and the extended line of the first envelope is defined as a reference line, an angle between a straight line that passes through the fixed point and the excitation section in the curved region including the first envelope and the reference line is defined, and an excitation angle of an angle between the reference line and an excitation direction of an acoustic wave at an intersection between the straight line that passes through the fixed point and the excitation section in the curved region and the electrode fingers is defined, a thicknesses of the dielectric film changes according to the respective angle or the excitation angle so that resonant frequencies and anti-resonant frequencies in all of the excitation sections of the plurality of curved regions are coincident or approximately coincident with each other.

26. The acoustic wave device according to claim 23, wherein
a piezoelectric single crystal is included in the piezoelectric body layer;
the piezoelectric body layer includes a propagation axis;
in each of the plurality of curved regions, when a center of a circle including the arc shape of each of the plurality of first electrode fingers and the plurality of second electrode fingers or a center of gravity of two foci of an ellipse including the elliptical arc is defined as a fixed point, a portion on any straight line passing through the fixed point in each of the plurality of curved regions is defined as an excitation section, a straight line extending parallel or substantially parallel to the propagation axis and passing through the fixed point is defined as a reference line, an angle between a straight line that passes through the fixed point and the excitation section in the curved region including the first envelope and the reference line is defined, and an excitation angle of an angle between the reference line and an excitation direction of an acoustic wave at an intersection between the straight line that passes through the fixed point and the excitation section in the curved region and the electrode fingers is defined, at least one of a duty ratio, electrode finger pitch, or thicknesses of the plurality of first electrode fingers and the plurality of second electrode fingers changes according to the respective angle or the excitation angle so that resonant frequencies and anti-resonant frequencies in all of the excitation sections of the plurality of curved regions are approximately coincident with each other.

27. The acoustic wave device according to claim 23 further comprising:
a dielectric film on the piezoelectric body layer and covering the IDT electrode; wherein
a piezoelectric single crystal is included in the piezoelectric body layer;
the piezoelectric body layer includes a propagation axis;
in each of the plurality of curved regions, when a center of a circle including the arc shape of each of the plurality of first electrode fingers and the plurality of second electrode fingers or a center of gravity of two foci of an ellipse including the elliptical arc is defined as a fixed point, a portion on any straight line passing through the fixed point in each of the plurality of curved regions is defined as an excitation section, a straight line extending parallel or substantially parallel to the propagation axis and passing through the fixed point is defined as a reference line, an angle between a straight line that passes through the fixed point and the excitation section in the curved region including the first envelope and the reference line is defined, and an excitation angle of an angle between the reference line and an excitation direction of an acoustic wave at an intersection between the straight line that passes through the fixed point and the excitation section in the curved region and the electrode fingers is defined, a thicknesses of the dielectric film changes according to the respective angle or the excitation angle so that resonant frequencies and anti-resonant frequencies in all of the excitation sections of the plurality of curved regions are approximately coincident with each other.

28. The acoustic wave device according to claim 1, wherein in the intersecting region, shapes of the plurality of first electrode fingers and the plurality of second electrode fingers in plan view include a linear shape.

29. The acoustic wave device according to claim 1 further comprising:
a pair of reflectors on the piezoelectric body layer, opposed to each other with the IDT electrode interposed therebetween and each including a plurality of reflector electrode fingers; wherein
shapes of the plurality of reflector electrode fingers in plan view include a curved shape.

30. The acoustic wave device according to claim 1, wherein
the piezoelectric substrate includes a supporting substrate; and
the piezoelectric body layer is on the supporting substrate.

31. The acoustic wave device according to claim 30, wherein the piezoelectric substrate includes an intermediate layer between the supporting substrate and the piezoelectric body layer.

32. The acoustic wave device according to claim 30, wherein a hollow portion is provided in the piezoelectric substrate, and a portion of the supporting substrate and a portion of the piezoelectric body layer are opposed to each other with the hollow portion interposed therebetween.

33. The acoustic wave device according to claim 1, wherein the piezoelectric substrate includes only the piezoelectric body layer.

34. A filter device comprising:
a plurality of acoustic wave resonators; wherein
at least one of the acoustic wave resonators is the acoustic wave device according to claim 1.
